(19) United States
(12) Patent Application Publication
(10) Pub. No.: US 2025/0158085 A1
(43) Pub. Date: May 15, 2025

(54) Ti MATERIAL FOR FUEL CELL SEPARATOR AND METHOD OF MANUFACTURING THE SAME

(71) Applicants: HYUNDAI MOTOR COMPANY, SEOUL (KR); KIA CORPORATION, SEOUL (KR)

(72) Inventors: Dong-Jae Choi, Seoul (KR); Jae-Woong Choi, Seongnam-si (KR)

(21) Appl. No.: 18/610,721

(22) Filed: Mar. 20, 2024

(30) Foreign Application Priority Data
Nov. 13, 2023 (KR) 10-2023-0156150

(51) Int. Cl. H01M 8/0215; C01G 23/047; C22F 1/18; C23C 14/06; C23C 14/16; C23C 14/58

(52) U.S. Cl. CPC H01M 8/0215; C01G 23/047; C22F 1/183; C23C 14/0605; C23C 14/16; C23C 14/5806; C23C 14/5853; C01P 2002/82; C01P 2002/85; C01P 2004/04; C01P 2006/40

(57) ABSTRACT

A method of manufacturing a Ti material for a fuel cell separator includes rolling a Ti raw material of a pure Ti material or a Ti alloy material, deposition coating Ti ion particles on the Ti raw material by physical vapor deposition (PVD), and oxidation heat treating to form a conductive oxide layer of a TiO₂₋ₓ(0<x<1) structure around the Ti ion particles deposited by the deposition coating. According to the present disclosure, the Ti material can be used to achieve both corrosion resistance and conductivity.

### CROSS REFERENCE TO RELATED APPLICATIONS

This application claims priority to Korean Patent Application No. 10-2023-0156150, filed on Nov. 13, 2023, which is incorporated herein by reference in its entirety.

### BACKGROUND

### Field of the Disclosure

The present disclosure relates to a Ti material that is applied to a fuel cell separator, and a method of manufacturing the same.

### Description of Related Art

The fuel cell separator is a component that allows hydrogen and oxygen to diffuse uniformly within a fuel cell stack and allows water and heat generated during a process of generating electricity to be discharged.

The form of oxide that Ti forms in a typical oxidizing environment, such as heat treatment or anodizing, is TiO₂, and a structure thereof exists as rutile, anatase, brookite, amorphous, or a mixture thereof, depending on oxidation conditions (temperature/time/pressure/solution, etc.). TiO₂ exists as the form of stable oxide on a surface of Ti, which is a raw material, forming a passivation layer, which exhibits very good corrosion resistance in a general environment. This may be considered a similar principle to the way in which corrosion resistance is achieved due to a very fine (within a few nanometers) oxide thin film layer, such as Cr₂O₃, present on a surface of an STS.

Ti material is being considered as a metal separator material for the fuel cell because of excellent mechanical properties (stiffness), mass productivity (stamping), and excellent resistance to corrosion compared to other metals in an operating environment of the fuel cell that the material has. However, while the aforementioned oxide thin film layer present on the surface of Ti serves to provide corrosion resistance to the material, it has simultaneously an insulating property, which makes it impossible to secure the conductivity that the separator should have, and thus the Ti material is not applicable by itself.

Therefore, a method of applying a conductive coating to the surface of Ti material has been mainly used as a method of applying Ti material as the separator of the fuel cell. Another method is to use the conductivity of TiO₂ oxide. By going through a specific process, TiO₂ can be transformed into an oxidized layer structure with a deficiency of O, or TiO₂₋ₓ formed under controlled conditions can be used to maintain the inherent corrosion resistance of Ti while achieving electrical properties (conductivity) that are a similar level to C. Recently, there has been active research on a technology using these properties, and there is potential for application in various fields such as electrode materials, catalysts, solar panels, biomaterials, and water electrolysis.

It is known that the reason why TiO₂₋ₓ exhibits conductivity is that when a localized deficiency of O atoms is induced in a rutile TiO₂ structure to form a regular crystallographic shear structure, this type of defect structure provides a path for electron movement, resulting in conductivity. According to what has been described in the literature and patents so far, a method of forming TiO₂₋ₓ can be divided into two forms. The first method is to form TiO₂₋ₓ directly from Ti of a raw material, in which TiO₂₋ₓ is formed through heat treatment at a specific temperature and time using a reducing agent under a atmosphere with controlled oxygen partial pressure and vacuum degree (patent references 1,2, and 3), and the second method is to form TiO₂₋ₓ directly through coating, in which dry TiO₂₋ₓ coating using PVD or CVD under a reducing atmosphere or wet coating of a sol-gel coating material containing TiO₂₋ₓ are performed.

However, it is rare to find cases where the coating is designed to satisfy both corrosion resistance and conductivity so as to be used on the separator for the fuel cell, and it is even more difficult to find cases of being commercialized. In order to manufacture commercially viable TI separator, manufacturing processes and costs, mass productivity and uniform quality, and long-term performance and durability needs to be satisfied. To this end, this is because there are many technical challenges to overcome.

For example, in case of the first method, the heat treatment conditions to form TIO₂₋ₓ are to maintain a high temperature of around 600 to 1000° C. for a long time in a state of restricted atmosphere (vacuum degree, low oxygen partial pressure, and reducing gas). Therefore, there are limitations in manufacturing process and cost. The case of performing the coating by the second method, can be advantageous in terms of uniform quality and productivity. However, in terms of durability, since the Ti oxide layer is not produced from the raw material, when applied to the separator, there are many cases where the durability is not satisfied, such as coating peeling in the corrosive environment of long-term fuel cell operation. Furthermore, in the separator for the fuel cell, commercially viable levels of manufacturing cost and durability are being demanded at an increasingly high level.

Examples of patents that have considered and applied all of these aspects to the separator using Ti as a raw material so far include Patent documents 1, 2, 3, 4, etc. These development patents all commonly use the properties of TiO₂₋ₓ produced from a Ti raw material, but focus on securing the conductivity mediated through C. In case of U.S. Pat. No. 10,199,661, a uniform TiO₂ oxide layer was formed on a Ti raw material by pickling or other methods, and then the TiO₂₋ₓ layer was formed by reduction plasma treatment (using H₂ gas) or 300° C. vacuum heat treatment. Then, C is coated on this oxide layer by forming a chemical bonding layer (Ti—O—C,N) by a CVD method. However, the TiO₂₋ₓ oxide layer formed by the reduction plasma and low-temperature vacuum heat treatment method is less corrosion resistant than the Ti oxide layer of the raw material formed under high-temperature (oxidizing) heat treatment conditions. In addition, since this process needs to be carried out under a vacuum atmosphere, the mass production and manufacturing cost are limited in terms of manufacturing process under normal production environmental conditions.

In this respect, JP Patent Publication No. 2019-133862 adopted a method of forming TiO₂₋ₓ on a surface of the raw material by oxidation heat treatment under high temperature and low oxygen partial pressure conditions In addition, a nano composite coating containing C was performed before the oxidation heat treatment, so that it was designed so that the C nano composite was embedded in the TiO₂₋ₓ oxide layer during the growth of the oxide layer in the process of heat treatment, and the thickness of the oxide layer was limited to 40 to 100 nm. However, since the oxygen partial pressure (3 to 30 Pa) and temperature conditions presented in the patent correspond to conditions that are out of equilibrium state to form TiO₂₋ₓ, the heat treatment time needs to be as short as less than one minute in a limited range of temperature. The reason for this is considered to form TiO₂₋ₓ, which is an oxide compound in a transitional state during the formation of TiO₂ at a given temperature-oxygen partial pressure condition, on the surface of the raw material. Although the TiO₂₋ₓ layer formed through high temperature oxidation heat treatment may increase the corrosion resistance to some extent compared to the method of Patent Document 1, there are limitations in securing further corrosion resistance due to limitations in the principle of forming the conductive oxide layer and process conditions (time limitation due to roll-to-roll coil heat treatment). In general, high-temperature oxidation heat treatment or positive electrode oxidation treatment is often performed to further increase the corrosion resistance of the Ti material, but the method of existing JP Patent Publication No. 2019-133862 cannot apply higher heat treatment temperature and time conditions to improve the corrosion resistance.

That is, the formation of a conductive TiO₂₋ₓ layer is possible only under the presented time-temperature conditions, and beyond this range, the conductivity decreases due to insufficient or excessive growth of the TiO₂ oxide layer, making it difficult to be applied to the separator. In case of C contained in the oxide layer, the growth of TiO2 by corrosion may serve to compensate for the conductivity to some extent, but when the corrosion progresses in a harsher corrosive environment or under long-term endurance conditions, the effect will be lost because the C-containing oxide layer or raw material falls off with the corrosion. Therefore, in the fuel cell corrosive environment that requires high durability, it is necessary to form a conductive oxide layer with more robust corrosion resistance on the Ti separator material itself, while developing a coating method that can maintain the performance.

In this respect, JP patent publication No. 2019-214781 presented a method of forming a TiO₂ oxide layer by oxidation heat treatment or anodizing in the atmosphere from the beginning, and then applying C to carry out an anoxic atmosphere or vacuum heat treatment. This focuses on the Ti oxide layer, where the diffusion of C into the TiO₂ layer proceeds during the heat treatment process, reducing the TiO₂ oxide to Ti₂O₃ and TiO, thus securing both conductivity and corrosion resistance. In particular, the upper limit value of the initial oxide layer was limited to 120 nm to prevent the resistance from increasing at an oxide layer thickness of greater than 120 nm. Although this method can further increase the oxide layer thickness for securing corrosion resistance compared to the conventional methods, there is a limitation in setting the conditions for additional oxide layer thickness for higher corrosion resistance because the method of forming the conductive oxide layer relies on the diffusion of C from the outermost of the oxide layer to the inside thereof. In addition, considering the region in which the conductive oxide layer is positioned, direct exposure to the corrosive environment cannot be avoided from the beginning, which may involve a problem of gradual performance degradation over time.

To summarize the fundamental problem with each of the patents described so far in terms of corrosion resistance, both methods have clear limitations in terms of heat treatment temperature and time conditions for setting the thickness of the conductive oxide layer to increase the corrosion resistance of the separator. In case of JP Patent Publication No. 2019-133862, there is a limitation on the temperature and time of the heat treatment because it is necessary to form TiO₂₋ₓ on the surface of the Ti raw material through a chemical reaction of Ti of the raw material with gas under a thermodynamically non-equilibrium condition (in a roll-to-roll process), and in case of JP patent publication No. 2019-214781, there is a limitation on the thickness of the initial oxide layer because the reduction reaction of TiO₂ needs to be induced to be mediated by C diffusing from the oxide layer of the Ti raw material under a given temperature and time condition. In addition, in terms of the manufacturing process, both methods have a disadvantage of undergoing a secondary heat treatment process in a vacuum atmosphere, and in each case, special production facilities that are generally difficult to be commercialized and facilities above a certain scale are required for mass production, which also may be a factor in increasing costs.

The above information disclosed in the related art is only for enhancement of understanding of the background of the present disclosure and therefore it may contain information that does not form the related art that is already known to a person of ordinary skill in the art.

### SUMMARY

The present disclosure has been made to solve the above-described problems, and the present disclosure is directed to providing a Ti material for a fuel cell separator that is capable of securing both corrosion resistance and conductivity using a Ti material, and a method of manufacturing the same.

According to one aspect of the present disclosure, there is provided a method of manufacturing Ti material for a fuel cell separator, the method including rolling a Ti raw material of a pure Ti material or a Ti alloy material, deposition coating Ti ion particles on the Ti raw material by physical vapor deposition (PVD), and oxidation heat treating to form a conductive oxide layer of a TiO₂₋ₓ(0<x<1) structure around the Ti ion particles deposited by the deposition coating.

Further, a portion of a surface oxide layer of the Ti raw material may be etched by Ar⁺ ions from the deposition coating.

Here, by the deposition coating, a Ti ion deposited layer may be formed on the surface oxide layer, on the etched surface of the Ti raw material and on an inside underneath the surface oxide layer of the Ti raw material, and an atomic intermix region may be formed in which the Ti of the surface oxide layer and the deposited Ti ion particles are mixed.

Further, the oxidation heat treating may be carried out in an atmospheric state, and in which Ti elements of the surface oxide layer and the Ti ion particles may be reacted with oxygen by the oxidation heat treating to form an atmospheric heat treated oxide layer.

More specifically, in the oxidation heat treating, the conductive oxide layer of the structure TiO₂₋ₓ(0<x<1) may be formed through diffusion rearrangement between Ti particles overdeposited within the Ti ion deposited layer, defects, and O particles introduced from the atmosphere or present within the surface oxide layer.

Further, the method may further include: coating C particles on the surface oxide layer and the Ti ion deposited layer after the deposition coating, in which the C particles may be diffused inside the surface oxide layer and the Ti ion deposited layer by the oxidation heat treating.

Further, the method may further include, after the rolling, Ar heat treating or vacuum heat treating the Ti raw material.

Meanwhile, an acceleration voltage of the deposition coating may be 80 to 250 eV.

In addition, an area fraction (covering %) on the surface of the Ti raw material of the Ti ion deposited layer may be 50 to 90%.

Further, a thickness of the conductive oxide layer may be 50 to 500 nm.

In addition, a heat treatment temperature of the oxidation heat treating may be 580 to 750° C., and a holding time may be 1 to 10 minutes.

Next, according to another aspect of the present disclosure, there is provided a Ti material for a fuel cell separator, the Ti material including: a Ti raw material made of a pure Ti material or a Ti alloy material; a surface oxide layer formed on the Ti raw material; a Ti ion deposited layer in which Ti ion particles are deposited and coated by physical vapor deposition (PVD) on the Ti raw material and on the surface oxide layer; and a conductive oxide layer formed in a TiO₂₋ₓ(0<x<1) structure around the deposited Ti ion particles.

Further, the Ti ion deposited layer may be formed on the Ti raw material in which a portion of the surface oxide layer is etched and exposed by Ar⁺ ions by the PVD.

In addition, the Ti ion deposited layer may be formed on the surface oxide layer, on the etched surface of the Ti raw material and on an inside underneath the surface oxide layer of the Ti raw material, and an atomic intermix region may be formed in which the Ti of the surface oxide layer and the deposited Ti ion particles are mixed.

Further, the Ti material may further include: an atmospheric heat treated oxide layer formed on the surface oxide layer and on a surface of the etched Ti raw material by reacting Ti elements of the surface oxide layer and the Ti ion particles with oxygen by the oxidation heat treating.

Further, by an oxidation heat treatment, the conductive oxide layer of the structure TiO₂₋ₓ(0<x<1) may be formed through diffusion rearrangement between Ti particles overdeposited within the Ti ion deposited layer, defects, and O particles introduced from the atmosphere or present within the surface oxide layer.

In addition, the Ti material may further include C particles coated on the surface oxide layer and on the Ti ion deposited layer and then diffused inside the surface oxide layer and the Ti ion deposited layer by an oxidation heat treatment.

Further, the Ti raw material may be Ar heat treated or vacuum heat treated.

Meanwhile, an area fraction (covering %) on the surface of the Ti raw material of the Ti ion deposited layer may be 50 to 90%.

In addition, a thickness of the conductive oxide layer may be 50 to 500 nm.

According to the present disclosure, the following advantages are achieved.

First, the process is simple and the coating is performed by applying an existing and widely commercialized process, which reduces costs and is suitable for mass production. The coating for Ti separator implemented in the present disclosure mainly includes a PVD process and a heat treatment process. First of all, Ti ion etching performed in the PVD process is a simple PVD process that is commonly used, rather than requiring additional equipment or being possible only under specific conditions like other conventional methods. In case of the heat treatment process, it is possible to implement the conductive oxide layer simply using a general heat treatment furnace under atmospheric conditions, rather than having to be performed under controlled atmospheric conditions such as low oxygen partial pressure and vacuum environment as in conventional methods to form TiO₂₋ₓ from the Ti raw material.

Second, there is an advantage of achieving higher conductivity than other methods, which is beneficial for improving and maintaining fuel cell performance. This allows a boundary between the conductive oxide layer and the raw material to be left undistinguished, while using the oxide layer of the raw material to impart conductivity to the Ti material. Therefore, it is possible to reduce contact resistance more effectively than conventional methods where a boundary exists. This can be achieved by physical deposition and heat treatment process of Ti, which is the same element as the raw material, such that the conductive oxide layer is continuously distributed at the boundary of the raw material and the oxide layer (Ti ion atomic intermix region), thereby eliminating or minimizing the boundary resistance.

Third, the coating was developed using a principle different from the existing concept to implement the conductive oxide layer, which can have superior durability (corrosion resistance) compared to conventional methods. In the conventional methods, the conductive oxide layer is formed directly from the Ti raw material by controlling the oxidation reaction of Ti, or by inducing the reduction reaction of TiO₂ using a reduction mediator to form TiO₂₋ₓ. However, these methods have a disadvantage in that the process conditions for the formation of the conductive oxide layer are very limited, leading to no further enhancement of corrosion resistance or structural weaknesses. In contrast, in the present disclosure, it is possible to set heat treatment conditions that can further increase corrosion resistance by forming the conductive oxide layer through the process of rearrangement by diffusion, and the structurally corrosion-resistant conductive oxide layer can be formed. In addition, it can be seen that the post-shaping processed sites of the coated material are also advantageous in terms of corrosion resistance.

### BRIEF DESCRIPTION OF THE FIGURES

FIG. 1 illustrates an overview of a method of manufacturing a Ti material for a fuel cell separator of the present disclosure.

FIGS. 2, 3, and 4 sequentially illustrate the Ti material for the fuel cell separator according to an embodiment of the present disclosure by the manufacturing method in FIG. 1.

FIGS. 5 and 6 sequentially illustrate a Ti material for a fuel cell separator according to an additional embodiment of the present disclosure by the manufacturing method in FIG. 1.

FIGS. 7 and 8 are surface cross-sections according to an embodiment of a rolling and heat treatment (Ar atmosphere) step of the manufacturing method of the present disclosure.

FIGS. 9 and 10 are surface cross-sections according to another embodiment of the rolling and heat treatment step.

FIGS. 11 and 12 illustrate an overview of a Ti ion etching step of the manufacturing method of the present disclosure.

Further, FIGS. 13, 14, and 15 sequentially illustrate the Ti material for the fuel cell separator according to an embodiment of the present disclosure with an Ar heat treated Ti raw material applied by the manufacturing method.

FIGS. 16, 17, and 18 sequentially illustrate the Ti material for the fuel cell separator according to an embodiment of the present disclosure with a vacuum heat treated Ti raw material applied by the manufacturing method.

FIGS. 19, 20, and 21 are TEM cross-sectional pictures of an oxide layer according to an embodiment of the present disclosure.

FIGS. 23, 24, and 25 are surface XPS depth profiles by oxidation heat treatment condition according to an embodiment of the present disclosure.

FIGS. 27 and 28 are RAMAN spectra by oxidation heat treatment condition according to an embodiment of the present disclosure.

### DETAILED DESCRIPTION

Hereinafter, embodiments of the present disclosure will be described in detail with reference to the exemplary accompanying drawings, and since these embodiments, as examples, may be implemented in various different forms by those skilled in the art to which the present disclosure pertains, they are not limited to the embodiments described herein.

In order to sufficiently understand the present disclosure, advantages in operation of the present disclosure, and the object to be achieved by carrying out the present disclosure, reference needs to be made to the accompanying drawings for illustrating an exemplary embodiment of the present disclosure and contents disclosed in the accompanying drawings.

Further, in the description of the present disclosure, the repetitive descriptions of publicly-known related technologies will be reduced or omitted when it is determined that the descriptions may unnecessarily obscure the subject matter of the present disclosure.

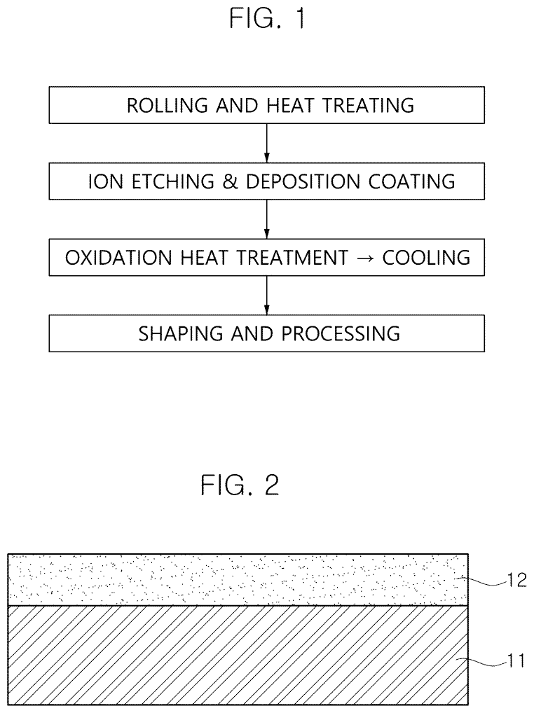

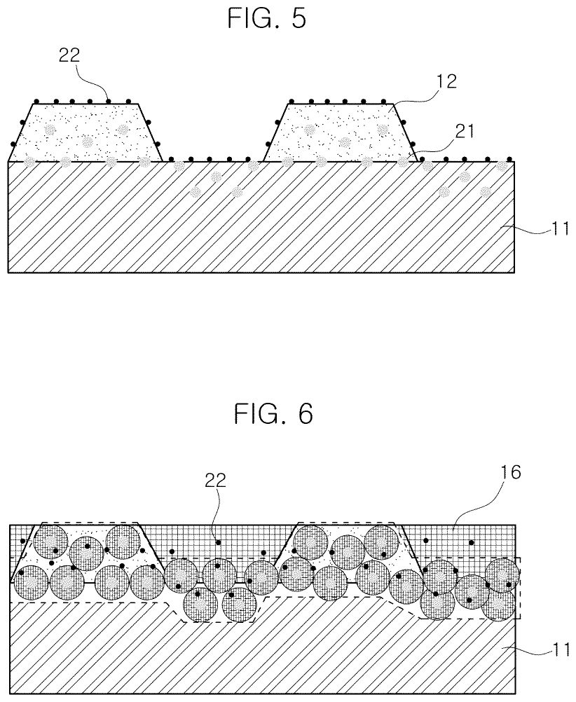

FIG. 1 illustrates an overview of a method of manufacturing a Ti material for a fuel cell separator of the present disclosure. Further, FIGS. 2 to 4 sequentially illustrate the Ti material for the fuel cell separator according to an embodiment of the present disclosure by the manufacturing method in FIG. 1, and FIGS. 5 and 6 sequentially illustrate a Ti material for a fuel cell separator according to an additional embodiment of the present disclosure by the manufacturing method in FIG. 1.

Hereinafter, with reference to FIGS. 1 to 6, a Ti material for a fuel cell separator according to the present disclosure and a method of manufacturing the same will be described.

The present disclosure has developed a material coating technology for a Ti separator for a fuel cell that is more effective in terms of performance and manufacturing process by using a combination of a PVD process and a heat treatment process, which is a non-equilibrium process, instead of an equilibrium-process method that uses only an oxidation, reduction reaction, or diffusion process like existing methods, in the principle of forming a conductive oxide layer on a Ti material. Therefore, in terms of performance compared to existing technologies, higher corrosion resistance and conductivity will be secured, while also having properties suitable for the pre-coating and post-molding processes. In addition, the present development has been carried out so that the manufacturing process becomes the process more suitable for the commercialization of Ti separator by implementing the technology using generally commercialized equipment under simple conditions.

The present disclosure relates to a Ti material for a metal fuel cell separator, and a method of manufacturing the same, and to a coating and surface treatment of the Ti material. Ti is a pure Ti material such as grade 1,2 or an alloy thereof, and the material may be in a state in which the material with a thickness of 0.3 mm or more from BA (Bright Annealing: a heat treatment process performed using nitrogen, hydrogen, argon, or a mixture of these gases, which are non-oxidizing gases, similar to the stainless steel bright annealing process) heat treatment is further rolled to the thickness required for the application of the separator (0.08 to 0.1 mm) (non-heat treatment) or a state in which the material is further heat treated to secure mechanical properties suitable for forming the separator after further rolling. In the present disclosure, a material was used in a heat treated state to obtain mechanical properties suitable for press molding before coating.

Next, as a coating method, in-chamber sheet or roll-to-roll coil coating was performed using a PVD (Physical Vapor Deposition) device (ion etch & vapor deposition coating), followed by an oxidation heat treatment to form a conductive oxide layer on a surface of the coated Ti separator. In this case, a heat treatment furnace capable of in-furnace atmosphere control such as vacuum and oxygen partial pressure may be used, but in general, a heat treatment furnace performed under an atmospheric state is acceptable.

Then, through molding and machining, the fuel cell separator for a negative and positive electrode may be manufactured.

With reference to FIGS. 2 to 4 more specifically, the material of a Ti raw material 11, which is a Ti raw material, is pure titanium or a titanium alloy. The pure titanium as used here means a material containing 98.8% or more of Ti. For example, the pure titanium may be one of the pure titanium materials in ASTM GRADE 1, 2, 3, or 4, which are highly economical and easy to machine. The titanium alloy is a material containing 70% or more of Ti with a balance of alloying and impurity elements. In the present development, it is preferable to use pure titanium as the base metal as a more suitable material for the separator.

With respect to the PVD and heat treatment process, the original purpose of the PVD technology is to form a physically uniform thin film layer on the material (target) to be coated together with a reactive gas in a vacuum plasma atmosphere. However, the purpose of the PVD process in the present disclosure is to simultaneously introduce an artificial overdeposition of Ti elements and structural disorder to the Ti raw material surface and the oxide layer region on the raw material surface in order to form a conductive TiO₂₋ₓ oxide layer on the Ti material surface. Therefore, during the heat treatment process, it is possible to form the conductive TiO₂₋ₓ(0<x<1) through diffusion rearrangement (restoration of structural disorder) between overdeposited Ti particles, defects and O particles (introduced from the atmosphere or present in the oxide layer on the surface of the base metal) within the localized region where the Ti particles were deposited. An example of this is shown below.

$$Ti ( s ) - ( 2 n - 1 ) TiO ( s ) \to 2 {Ti}_{n} {O}_{2 n - 1 ( s )}$$

$${n TiO}_{2} + Vo \to {Ti}_{n} {O}_{2 n - 1}$$

The PVD methods capable of implementing the aforementioned processes include ion plating, bias sputtering, ion beam assisted deposition (IBAD), and the like. The advantage of these methods is that while Ti⁺ ions are deposited, Ar⁺ ions simultaneously are collided, which not only partially removes (etches) the oxide layer on the surface, but also transfers energy to a Ti ion deposited layer 13 and below a surface of the Ti raw material 11, resulting in displacement in a crystal structure and consistent formation of an atomic intermix layer between Ti ion particles 21 deposited and the Ti raw material 11. Then, after heat treatment, a conductive oxide layer 15 with good corrosion resistance and adhesion is formed in this region.

Hereinafter, the PVD process will be referred to as “Ti ion etching”.

Hereinafter, describing the structure of the Ti conductive oxide layer more specifically, first, a surface oxide layer 12 of the Ti raw material 11 is formed by a process of rolling to a thickness suitable for use as a separator material and undergoing a heat treatment process to secure formability. The surface oxide layer 12 of the Ti raw material 11 may include all states in which the BA heat treated raw material has been 1) only rolled to a thickness of 0.08 to 0.15 t only (unheated material) and after rolling, 2) subjected to Ar heat treatment in a low oxygen atmosphere, or 3) subjected to vacuum heat treatment. All three states have the TiO₂ surface oxide layer 12 on the surface of the raw material, but the thickness and structure of the layer may vary throughout the process.

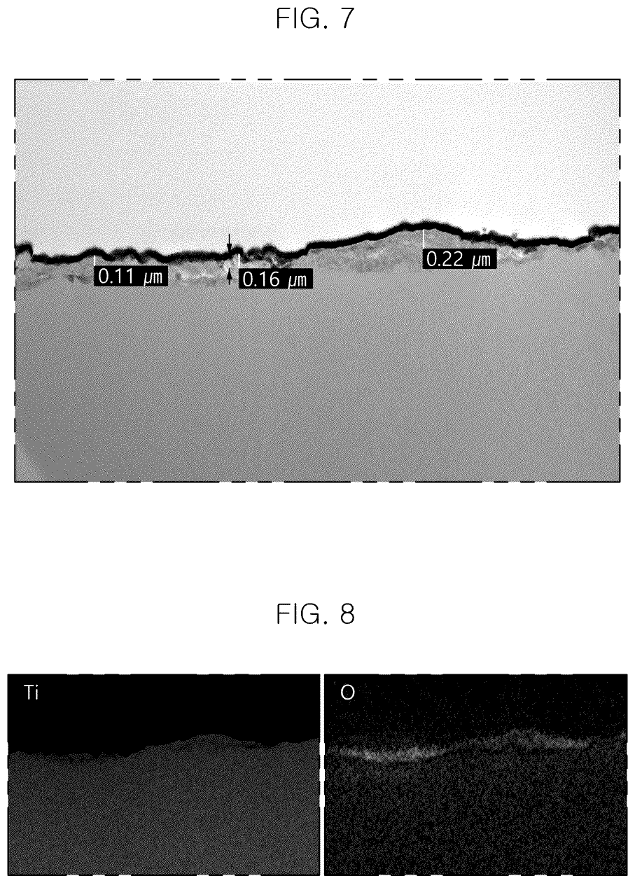

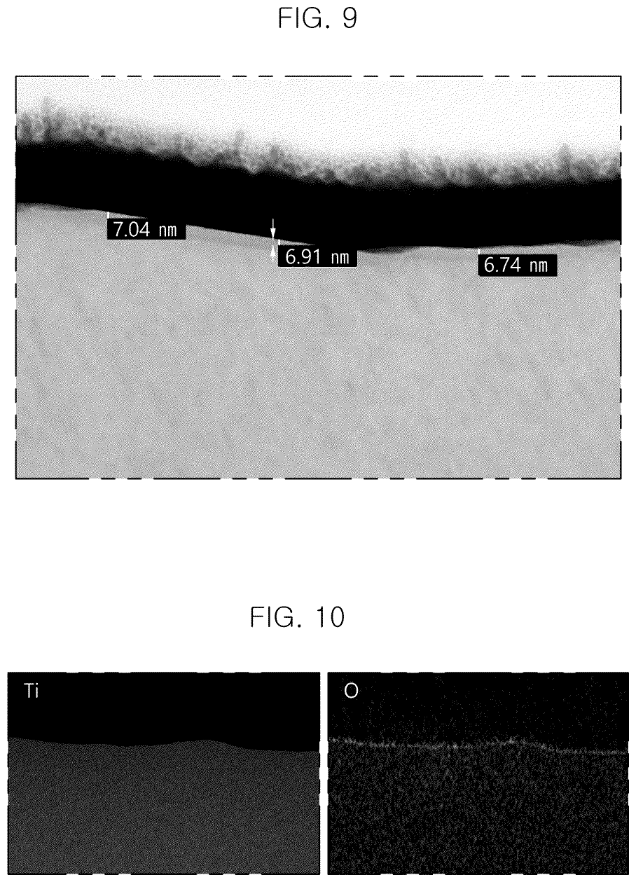

FIGS. 7 to 10 are cross-sectional and EDS component mapping photographs of the surface oxide layer according to the heat treatment of the Ti raw material, in which FIGS. 7 to 8 are Ar heat treated Ti raw material with the surface oxide layer of 100 to 200 nm, and FIGS. 9 to 10 illustrate vacuum heat treated Ti raw material with the surface oxide layer of less than 10 nm. That is, the thickness of the surface oxide layer is in the range of several nm to several hundred nm, and the thickness becomes thinner and more uniform in the order of non-heat treatment, Ar heat treatment, and vacuum heat treatment.

Next, the Ti ion particles 21 by Ti ion etching are distributed inside the surface oxide layer 12 of the Ti raw material 11 and at a surface boundary. These Ti ion particles 21 are also deposited on the surface oxide layer of the Ti raw material during the PVD process and on the surface of the raw material where the oxide layer is removed by Ar⁺ ion bombardment.

Including the surface oxide layer of the Ti raw material, a structurally irregular disorder region is formed near the surface where the surface oxide layer 12 of the Ti raw material 11 is partially removed by the Ar⁺ ion bombardment (e.g., vacancies, intrusive Ti ions, lattice displacement defects, etc.). In this region, diffusion of Ti ions by collision energy with the Ti ion deposited layer 13 results in an atomic intermix region (atomic intermix region) near the surface of the raw material.

The atomic intermix region refers to a region in a mixed state between Ti particles deposited by PVD and the raw material Ti. This layer has a gradual transition pattern from the inside of the raw material to the surface depending on the deposition depth of the Ti ions, and serves to maintain the bonding force between the conductive oxide layer 15 and the raw material.

Next, when subjected to a heat treatment process, the conductive oxide layer 15 is formed in a region around the Ti ion deposited particles.

There are regions where the oxide layer structure has been rearranged from TiO₂ to Ti₁₊ₓO₂ (0<x<1) structure during the heat treatment process due to an increase in a Ti/TiO₂ fraction around the Ti particles deposited inside the surface oxide layer 12 of the Ti raw material 11. (For convenience, the chemical notation for the conductive oxide formed structurally through diffusion rearrangement of overdeposited Ti particles and defects will be denoted as such.)

In addition, when the penetration depth of Ti ion deposition reaches the surface of the raw material and the region below, Ti₁₊ₓO₂(0<x<1) is formed in the atomic intermix region due to the diffusion rearrangement of defects formed by the collision of overdeposited Ti particles and Ar⁺ ions. The TiO₁₊ₓO₂ region formed around the Ti ion deposited particles, from within the outer oxide layer to the atomic intermix region of the raw material, forms the conductive oxide layer 15.

Next, there exists an atmospheric heat treated oxide layer 16 in the oxide layer existing at the outermost of the Ti raw material 11, which is generated by the reaction of Ti elements outwardly diffused from the raw material and the Ti ion deposited particles themselves with oxygen during the heat treatment process, and this region is also mixed with Ti₁₊ₓO₂ regions by some Ti ion deposited particles. The atmospheric heat treated oxide layer 16 thus formed may serve to impart higher corrosion resistance to the separator depending on the heat treatment temperature and time conditions.

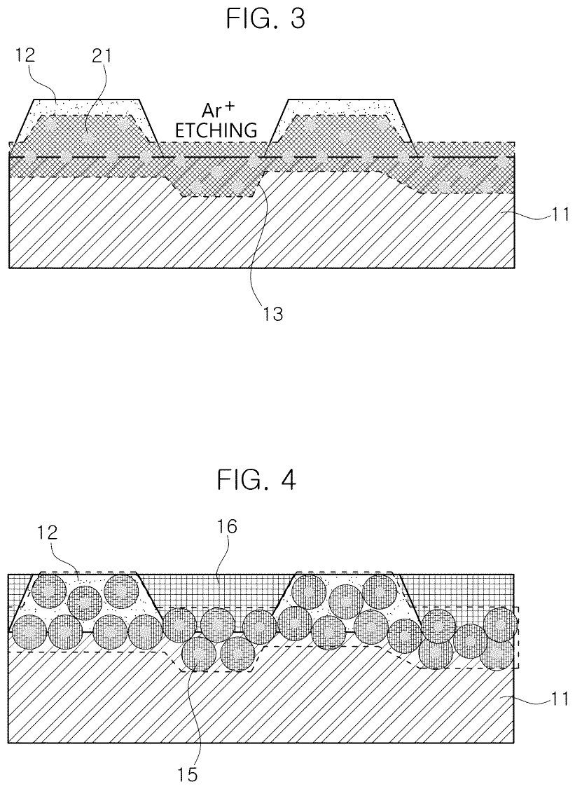

In contrast, FIGS. 5 and 6 illustrate a case with a C coating. When the C coating is performed after Ti ion etching in the PVD process in FIG. 3, C particles 22 diffuse into the oxide layer during the oxidation heat treatment and are included in the oxide layer, or are combined with the Ti ion particles 21 or the outwardly diffusing raw material Ti, as illustrated in FIG. 6. The other C particles 22 either induce further reduction reactions in the TiO2 layer or contribute to the conductivity by themselves.

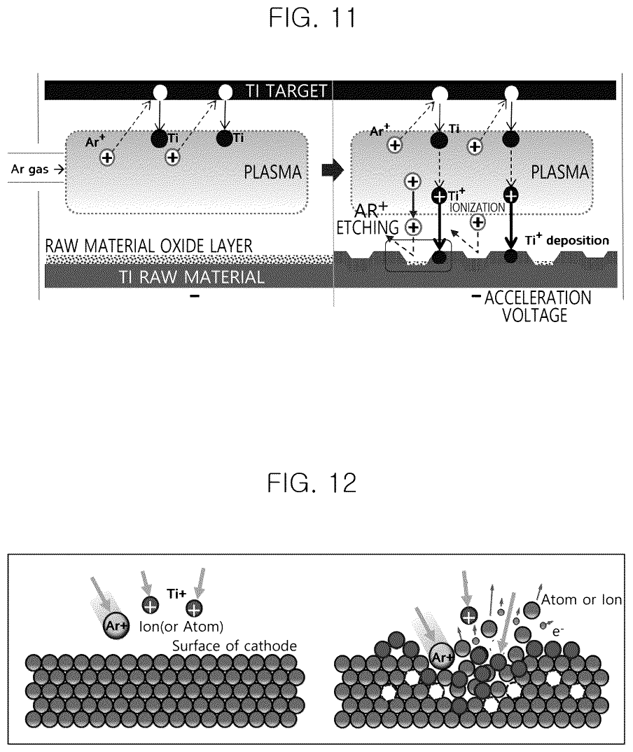

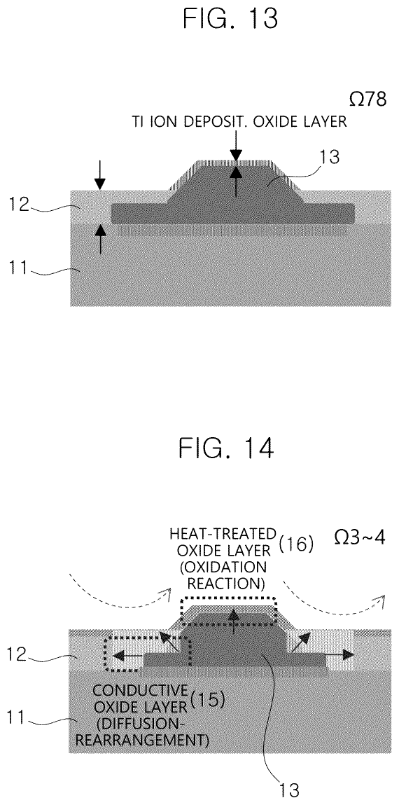

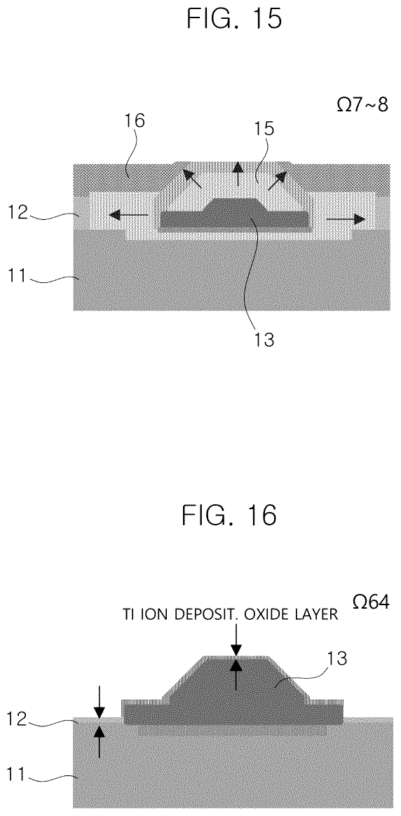

Next, FIGS. 11 and 12 illustrate an overview of a Ti ion etching step of the manufacturing method of the present disclosure. Further, FIGS. 13 to 15 sequentially illustrate the Ti material for the fuel cell separator according to an embodiment of the present disclosure with an Ar heat treated Ti raw material applied by the manufacturing method, and FIGS. 16 to 18 sequentially illustrate the Ti material for the fuel cell separator according to an embodiment of the present disclosure with a vacuum heat treated Ti raw material applied by the manufacturing method.

With reference to this, the steps of the manufacturing method of the present disclosure will be described in more detail.

### 1) Ti Ion Etching by PVD Device

In the present disclosure, the purpose of the PVD process is to artificially introduce an overdeposition of Ti and structural disorder in the interfacial region between a surface of the Ti raw material 11 and the surface oxide layer 12 through methods such as ion plating, bias sputtering, or ion beam assisted deposition (IBAD). To this end, the PVD process step includes Ti ion etching and C-PVD processes, which can be performed either by Ti ion etching only or by Ti ion etching and C-PVD together, depending on the properties required by the separator plate for the fuel cell.

The Ti ion etching is a process in which Ar⁺ ion bombardment and Ti ion deposition occur simultaneously on the surface of the Ti raw material 11. While Ti⁺ ions ionized in the plasma state are accelerated with a high voltage and deposited on the surface, Ar⁺ ions also collide with the raw material, removing oxides from the surface and causing disorder (lattice displacement, vacancy, etc.) in the surface structure of the raw material. This collision energy contributes to the homogenization of the Ti deposited layer as well as the diffusion of the deposited Ti particles into the raw material to serve to form the atomic intermix layer (see FIGS. 11 and 12). In this way, during the heat treatment process, the diffusion rearrangement between the physically overdeposited Ti particles and defects within the localized region of the interface where the Ti particles are deposited and the O particles introduced from the surface oxide layer of the raw material or from the atmosphere is achieved, and the formation of conductive TiO₂₋ₓ is possible in the process of restoring this structural disorder. That is, as a method of enabling the Ti oxide layer to have conductivity, in the conventional method, a chemical reaction (a method of forming TiO₂₋ₓ by reaction of Ti and O under heat treatment conditions of reducing gas or low oxygen partial pressure or a method of reducing TiO₂ to TiO₂₋ₓ by using a reduction catalyst such as C) was used under a specific condition to induce a deficiency of O in the TiO₂ structure to form TiO₂₋ₓ, whereas in the present development, the fraction of Ti particles was forcibly increased in the TiO₂ structure and then the Ti particles were rearranged through diffusion to form Ti₁₊ₓO₂ to impart conductivity.

With this diffusion rearrangement mechanism, the formation of TiO₂₋ₓ, which is only possible at low oxygen partial pressures and limited temperature and time conditions as in conventional patented or literature methods, can be achieved by atmospheric heat treatment only, and the constraints on heat treatment temperature and time conditions can be reduced to realize additional increase in corrosion resistance through strengthening of the outermost TiO₂ oxide layer, which is a protective layer. In addition, no special pretreatment process is required to control impurities prior to coating, and it can be applied relatively independent of the state of the oxide layer surface of the Ti raw material, thereby reducing various conditions of Ti raw material pretreatment constraints that have been required for the process of separator so far.

In addition, the Ti ion etching inhibits the uneven growth of the Ti oxide layer in the atmospheric heat treatment conditions of the subsequent process, facilitating the control and condition establishment of the oxidation heat treatment process. In general, the growth of the Ti oxide layer by heat treatment is achieved by the reaction of Ti diffused outward from the raw material with external O. However, in case of performing the Ti ion etching, in addition to the formation of the outermost oxide layer, a certain amount of O introduced from the atmosphere is absorbed into the disorder region by ion bombardment with the Ti deposition on the surface of the raw material and is consumed to form Ti₁₊ₓO₂. This provides the temperature and time conditions for the heat treatment needed to more reliably secure the targeted resistance value.

In the present disclosure, the purpose of the Ti ion etching process is not to form a general coating layer, but to increase the fraction of Ti particles in the oxide layer and surface of the raw material, and at the same time to introduce defects to promote the diffusion and rearrangement of Ti particles during the heat treatment process to form a TiO₂₋ₓ structure. Therefore, in order to ensure that the atomic intermix region is formed in consideration of the collision effect of Ar⁺ ions and the bonding force of Ti ions positioned on the surface of the raw material, the acceleration voltage may range from 80 to 800 V, and a more appropriate voltage may range from 180 to 250 eV. At an acceleration voltage more than the range above, the Ar⁺ ions may not cause a collision effect on the surface of the raw material and the Ti deposited layer, but instead penetrate into the raw material, and the Ti ions may also be implanted inside the raw material rather than positioned on the surface of the raw material, which makes the formation of the conductive oxide layer 15 difficult. In addition, at an acceleration voltage less than the range above, when the collision effect of the Ar⁺ ions is insufficient to form the conductive oxide layer 15 through heat treatment, or when the atomic intermix region is not formed due to insufficient Ti ion bombardment energy, there may be problems with the degraded corrosion resistance and durability of a shaping processed part due to insufficient bonding force of the conductive oxide layer 15.

For the Ti ion etching time, the Ti ion etching is performed for 1 to 4 minutes so that the covering (%) of the Ti ion deposition is not excessive or insufficient, and more preferably, 2 to 3 minutes. When the covering of the Ti ion deposition is excessive for a longer time than the above, the formation of the conductive oxide layer 15 may become difficult because the resistance is increased by the oxidation of the outer Ti ion deposited particles during the heat treatment process and the diffusion of the O particles into the oxide layer due to this oxide layer is blocked. At a shorter time than the above, the amount of deposited Ti ions becomes insufficient, making it difficult to expect the formation of the conductive oxide layer 15 by increasing the Ti fraction inside the oxide layer or on the surface of the raw material, and even if the conductive oxide is formed, the proportion of insulating oxide on the outer side becomes relatively high during the same heat treatment time, making it difficult to secure stable conductivity. As a result, depending on the acceleration voltage and time of the Ti ion etching, an area fraction of the Ti ion deposition covering the surface of the raw material (covering %) of 50 to 90% of a total surface of the raw material is appropriate, and a thickness of 50 to 200 nm is appropriate. A thickness that forms the conductive oxide layer 15 from the periphery of the Ti ion deposition to the atomic intermix region may be at least 50 to 500 nm. The following Table 1 shows the change in contact resistance with Ti ion etching time and oxidation heat treatment, and FIGS. 15 to 20 illustrate schematic views of the change in contact resistance as heat treatment progresses for each Ti raw material condition.

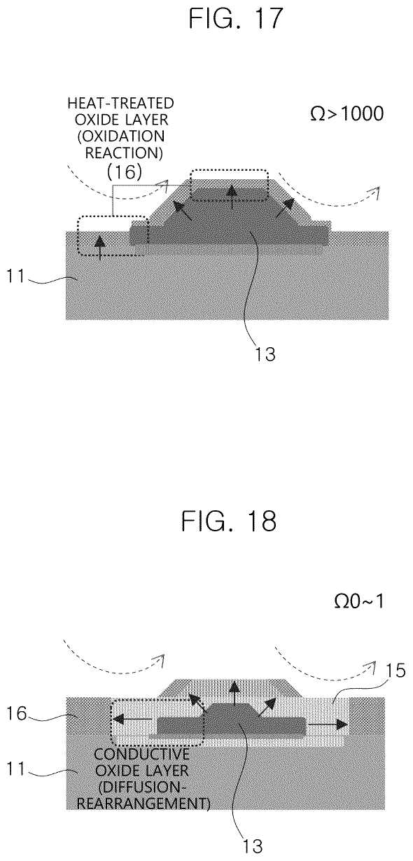

FIGS. 13 to 15 illustrate Ti raw material with Ar heat treated, in which FIG. 13 illustrates a Ti raw material before the heat treatment, FIG. 14 illustrates a Ti raw material subjected to an oxidation heat treatment for 3 minutes, and FIG. 15 illustrates a Ti raw material subjected to an oxidation heat treatment for 5 minutes. Further, FIGS. 16 to 18 are for Ti raw material with vacuum heat treated, in which FIG. 16 illustrates a case before the heat treatment, FIG. 17 illustrates a case an oxidation heat treatment of 3 minutes, and FIG. 18 illustrates an oxidation heat treatment of 5 minutes.

TABLE 1

| Ti Ion Etching | | Oxidation heat | | | | | |
|---|---|---|---|---|---|---|---|
| Acceleration | | treatment | | Change in contact resistance (mΩ-cm2) | | | |
| Voltage | Time | Time | | 1 min. | 3 min. | 5 min. | 10 min. |
| 180 eV | 30 sec. | Temper- | 600° C. | 80 to 90 | 180 to 300 | 700 to 1300 | 1 to 2 or more than |
| | | ature | | | | | 1000 sec (non- |
| | | | | | | | uniform resistance) |
| | 2 min. | | | — | Greater | 0 to 1 | 0 to 1 |
| | | | | | than 1000 | | |
| | 4 min. | | | — | 340 | 460 to 500 | 650 to 1000 |

### 2) Oxidation Heat Treatment

The oxidation heat treatment process is used to impart conductivity and corrosion-resistant properties to the surface of the separator after Ti ion etching. In the present disclosure, the oxidation heat treatment may be carried out by an atmospheric heat treatment rather than under specially controlled atmosphere conditions, and may be carried out by controlling a type of gas and partial pressure of oxygen for more stable quality. The process sequence includes heating the separator by exposing the separator, which is to be subjected to heat treatment, to a target temperature, then holding the separator at the corresponding temperature for a certain period of time, followed by air cooling.

The process of securing conductivity is made possible by inducing outward diffusion of Ti atoms of the raw material during the oxidation heat treatment temperature-time and diffusion of overdeposited Ti atoms by Ti ion deposition, which changes the structure of the TiO₂ oxide layer of the raw material or the TiO₂ oxide layer further produced by the heat treatment into Ti₁₊ₓO₂. Therefore, in terms of securing conductivity, the oxidation heat treatment temperature-time conditions are determined by the energy required for the diffusion of deposited Ti atoms within the TiO₂ oxide layer, a diffusion rate, and the formation of the Ti₁₊ₓO₂ structure by diffusion rearrangement of Ti, O particles. Based on the experimental results, the heat treatment temperature range of 580 to 750° C. and holding time of 1 to 10 minutes are suitable for this process, and the results are shown in Table 2.

When the heat treatment temperature is below 580° C., the energy required for diffusion may be insufficient, and when exceeding 750° C., the rapid growth of the oxide layer may increase the resistance. In addition, a holding time of less than one minute may not provide enough time for diffusion and rearrangement, and a holding time of more than 10 minutes may result in excessive growth of the oxide layer, making it impossible to achieve the targeted conductivity.

The condition of the corrosion resistance of the separator may be set within a temperature and time range that ensures the targeted conductivity. In general, the corrosion resistance or oxidation resistance of the Ti material may be further increased through heat treatment, which is related to the thickness, composition and structure of the Ti oxide layer. Among the chemical bonding states of conductive TiO₂₋ₓ, Ti₂O₃, TiO, etc., which are stoichiometric compound states, are known to have better corrosion resistance than non-stoichiometric compound states (TiO 1.8,1.9 . . . ). The corrosion resistance of the Ti raw material that has undergone anodizing or oxidation heat treatment is superior to that of the untreated Ti. It was also confirmed in the present disclosure that, within the range of securing conductivity, it is possible to have better corrosion resistance in the fuel cell corrosion environment when subjected to a higher temperature and a longer holding time. This was especially obvious in a severe condition corrosion evaluation, where a heat treatment time of 5 to 10 minutes in the range of 680 to 720° C. was highly discriminative of corrosion resistance.

It can be seen that in case of performing the C coating, the inflow of O into the oxide layer is blocked at the outermost of the coating due to the C layer, so the formation of Ti₁₊ₓO₂ is delayed and the decrease in contact resistance appears slightly later as compared to when the C layer is not present. It is considered that this is because a decrease in contact resistance is caused by the influx of O and the diffusion of Ti ion deposited particles at a given temperature, starting from the occasion when the diffusion of C proceeds into the oxide layer. Therefore, it is preferable to hold for approximately 1 to 3 minutes longer compared to when there is no C layer in consideration of the delay time caused by the C coating. As described above, it was found that the corrosion resistance was more dominant when held at a high temperature and for a long period of time, in which case the heat treatment time and temperature condition is preferably 5 to 10 minutes in the range of 680 to 720° C.

TABLE 2

| Raw material | PVD | Heat treatment | | Contact resistance (mΩ-cm²) | | | | |
|---|---|---|---|---|---|---|---|---|
| (contact resistance) | (contact resistance) | Temperature (° C.) | | 600 | 620 | 650 | 670 | 690 |
| Ar heat | Ti ion | Time | 1.5 min. | — | — | 0 to 1 | 0 to 1 | 0 to 1 |
| treatment | etching | | 3 min. | 0 to 1 | — | 1 to 2 | 3 to 4 | 5 to 10 |
| (22 to 30) | (78) | | 5 min. | 0 to 1 | 0 to 1 | 3 to 4 | 7 to 8 | 6 to 12 |
| | | | 10 min. | 0 to 1 | — | — | — | 8 to 14 |
| | Ti ion | | 1.5 min. | — | — | 800 to 900 | 1500 to 1700 | 0 to 1 |
| | etching + | | 3 min. | 700 to 800 | — | — | 0 to 1 | 0 to 1 |
| | C-deposition | | 5 min. | — | — | 0 to 1 | — | 6 to 7 |
| | (78) | | 10 min. | 0 to 1 | — | — | — | 0 to 1 |
| Vacuum | Ti ion | | 3 min. | — | — | 1000 | 1300 to 1400 | 0 to 1 |
| heat | etching | | 5 min. | — | 800 to 850 | 1600 to 1850 | 0 to 1 | 0 to 1 |
| treating | (64) | | | | | | | |
| (18 to 20) | Ti ion | | 5 min. | — | — | — | — | 0 to 1 |
| | etching + | | | | | | | |
| | C-deposition | | | | | | | |
| | (56) | | | | | | | |

In the following, the aspects of the conductive oxide layer and corrosion resistance enhancement are described.

### 1) Formation of Conductive Oxide Layer

In general, it is known that the formation of TiO₂₋ₓ under a controlled atmosphere (oxygen partial pressure, temperature, etc.) depends on the reaction of O and Ti at the boundary of the raw material and the oxide layer, which is affected by the diffusivity of O and Ti elements within the oxide layer on the surface of the raw material. Since the diffusivity of O in the TiO₂ oxide layer is high, while that of Ti is relatively low, the fraction of Ti outwardly diffused from the raw material in the boundary region between the raw material and the oxide layer becomes relatively high when the amount of O supplied to the oxide layer during heat treatment is limited, and the formation of TiO₂₋ₓ by a localized O deficiency in the oxidation reaction of Ti becomes possible. The TiO₂₋ₓ phase formed as described above is achieved through an equilibrium process that depends on the diffusion and chemical reaction of Ti and O atoms.

One of the other methods to form TiO₂₋ₓ is a method of Ar⁺ sputtering the surface of the TiO₂ oxide layer using PVD equipment, followed by heat treatment under vacuum.

This uses the principle that TiO₂₋ₓ is formed due to the increased diffusivity of the Ti element and localized O deficiency in the process where the structural disorder artificially introduced into the crystal structure of the oxide layer and raw material surface by Ar⁺ sputtering is restored by heat treatment. The Ar⁺ sputtering as such includes a non-equilibrium process. However, the reduction of the TiO₂ layer to TiO₂₋ₓ was only possible by repeated Ar⁺ sputtering or by heat treatment at a high temperature (>1000) for several hours under vacuum.

As described above, the important factors in the formation reaction of TiO₂₋ₓ are 1) the diffusivity of Ti and 2) the relative ratio of Ti to O at the boundary of the raw material and the oxide layer. When Ar⁺ ions collide with the surface of the Ti raw material, a certain degree of disorder is induced in the TiO₂ oxide layer on the surface and the crystal structure of the Ti raw material. In this case, when Ti ions are deposited on the surface of the raw material with an acceleration voltage of tens to hundreds of eV in addition to Ar⁺ ion etching, the ratio of Ti element content inside the TiO₂ oxide layer and on the surface of the raw material and on the surface of the raw material may be forced to increase. That is, when Ar⁺ ion etching and Ti ion deposition are performed simultaneously, the accumulated defect energy, including vacancies, interstitials, and atomic displacements due to Ar⁺ ion bombardment, can promote the diffusion of Ti and O atoms (especially with the effect of lowering an activation E required for the diffusion of Ti). In addition, the intervention of artificially increased Ti particles in the process of the rearrangement of Ti and O during heat treatment causes an off-stoichiometry of TiO₂. That is, for the deficiency or removal of O from TiO₂, the formation of the conductive oxide (Ti₁₊ₓO₂) was achieved through structural changes by diffusion rearrangement of artificially (PVD method) overdeposited Ti particles and defects in the crystal structure rather than through diffusion and chemical reactions in equilibrium.

In summary, the conductive oxide layer was implemented by forming structurally conductive non-stoichiometric Ti oxides, i.e., Ti₁₊ₓO₂, in the process where the defects were recovered through diffusion and rearrangement of Ti and O by artificially introducing overdeposited Ti particles and structural defects at the boundary of the oxide layer and the Ti raw material surface through Ti ion etching, and then proceeding with heat treatment under appropriate temperature and time conditions.

Therefore, it is possible to form TiO₂₋ₓ or Ti₁₊O₂ through the segregation of these elements within several minutes at a relatively low temperature (600 to 700° C.) using a non-equilibrium process by PVD, even if the heat treatment is not performed at a high temperature (>1000° C.) for several hours as in conventional methods. In addition, since the phenomenon of diffusion rearrangement of Ti, O elements in the already existing Ti raw material oxide layer and raw material surface is used, there is no need for vacuum or low oxygen partial pressure conditions required for oxidation or reduction reactions as in conventional methods, and it is possible to secure conductivity by the formation of TiO₂₋ₓ or Ti₁₊O₂ even through atmospheric state heat treatment.

In the present disclosure, the reason for depositing Ti particles through Ti ion etching method (such as ion plating, bias sputtering or IBAD) rather than ion implantation is that in case of the ion implantation, the surface properties of the deposited particles are changed in the process of penetrating into the raw material, while the Ti ion etching may form a fine coating layer without changing the surface properties of the raw material. That is, the oxide layer of the raw material may be maintained and used to more effectively form the conductive oxide layer, and since this method serves as both coating and sputtering, it is possible for the Ti ion deposited particles to be distributed inside the oxide layer on the surface of the raw material, outside the surface of the raw material, and even inside some of the raw material to form the atomic intermix layer. When Ti ion deposited particles are continuously present through a gradual transition from the oxide layer to the atomic intermix region beneath the surface of the raw material, the stress caused by the formation of the deposited layer can be minimized, and it has an advantage in that the adhesive force of the coating layer remains excellent even after heat treatment. Therefore, it is possible to achieve a more durable conductive oxide layer structure even in a coating method for the separator with a [pre-coating-post-processing]approach, such as the roll-to-roll PVD process.

Another advantage of this method of forming the conductive oxide layer is that it is possible to secure higher conductivity compared to conventional methods, relatively independent of the thickness of the oxide layer formed on the surface through heat treatment. In the conventional method, since the boundary between the conductive oxide layer and the raw material is discontinuous or a fine insulating boundary layer exists, the resistance increases accordingly, and the conductivity tends to decrease rapidly when the thickness of the oxide layer on the surface exceeds a certain level (approximately 100 to 200 nm). However, since the position where the conductive oxide layer is distributed by Ti ion deposition continuously exists from the atomic intermix region in contact with the bulk of the raw material to the boundary between the raw material and the oxide layer on the surface as well as the outer oxide layer, the boundary between the raw material and the conductive oxide layer is not distinguished, and as a result, the method of the present disclosure exhibits higher conductivity even if the thickness of the oxide layer is thicker than other conventional methods. This result can be confirmed from the result values of measuring the contact resistance of the example and comparative example in Table 1.

### 2) Enhancement of Corrosion Resistance

A further advantage of the method of forming a conductive coating by Ti ion etching and heat treatment according to the present disclosure is that it has very excellent corrosion resistance in a fuel cell corrosive environment compared to the coating for Ti separator implemented by the conventional methods. This enhanced corrosion resistance may be described by the formation position, shape, and structure of the conductive oxide layer.

### Position of Conductive Oxide Layer

The position of the conductive oxide layer, which is produced in the process of imparting conductivity by modifying TiO₂, the oxide layer of Ti itself, to TiO₂₋ₓ, varies slightly depending on the method and process. For example, the conventional TiO₂₋ₓ formation process is achieved through the reaction of Ti and O from the surface by outward diffusion of the raw material Ti in a vacuum and reducing atmosphere, or through a reduction reaction that occurs from the outermost of the oxide layer mediated by the direct application of a reducing agent to the surface of the oxide layer. In both cases, the oxide layer of the Ti raw material is used, resulting in superior corrosion resistance compared to other methods that use a coating of heterogeneous materials. However, the position of the conductive oxide layer exists in the outermost due to the method, thus being directly exposed to the corrosive environment. In the former case, there is a boundary between the surface of the raw material and the conductive oxide layer formed thereon, which may increase the resistance in case of self-dissipation of the conductive oxide layer in a long-term harsh fuel cell corrosive environment, and in the latter case, the conductive oxide layer exists in the outermost, and therefore is preferentially attacked by the corrosive environment, which may lead to loss of function. However, in the present disclosure, the conductive oxide layer is formed near the surface of the raw material, which is the innermost of the entire oxide layer, and at the boundary of the oxide layer by the Ti ion etching and heat treatment process. Therefore, the conductive oxide layer is not exposed to the external corrosive environment, but is protected from the outer oxide layer formed by the heat treatment, and can maintain the performance in the harsh corrosive environment for a longer period of time.

### Shape of Conductive Oxide Layer

The corrosion resistance of a metal material is also closely related to the shape of the oxide layer on the surface of the raw material. When the oxide layer contains many defects, such as microcracks or porous structures, these defects provide diffusion paths for aggressive negative ions and oxygen in the corrosive environment, causing adsorption and corrosion of these elements at the interface of the raw material and the oxide layer, thus losing the effectiveness as a protective layer. In particular, when there is a distinct boundary between the raw material and the coating or between the raw material and the oxide layer, the galvanic coupling phenomenon due to the difference in electrochemical potential of the two regions promotes the delamination of the coating or oxide layer. In general, the oxide layer on the surface of Ti material that has undergone atmospheric oxidation heat treatment to increase the corrosion resistance of Ti is composed of a porous TiO₂ oxide layer on the outer surface and a compact and thin TiO₂+TiOₓ layer on the inner surface, and in a harsh corrosive environment containing aggressive negative ions, the corrosion resistance is mainly determined by the inner layer.

Even if the conductive oxide layer formed by the reaction of Ti and O on the surface of the raw material according to the conventional method has a TiO₂+TiO₂₋ₓ structure, sufficient thickness may not be secured due to the extremely limited temperature and time conditions of the oxidation heat treatment, and the boundary between the raw material and the oxide layer is distinguished, which has limitations in increasing the corrosion resistance. However, when the conductive oxide layer is implemented through Ti ion deposition and heat treatment as in the present disclosure, there is no boundary between the raw material and the conductive oxide layer because the atomic intermix region is converted into the conductive oxide layer and included in the raw material, and a compact layer is formed by increasing the Ti fraction and diffusion and rearrangement rather than growth by the oxidation reaction. Therefore, it is possible to have superior corrosion resistance in terms of structure shape compared to other methods. In addition, since the conductive oxide layer formed in this way has excellent bonding force with the raw material, it is possible to minimize the deterioration of the corrosion resistance of a processed part, which is a vulnerable part in the [pre-coating-post-forming]method.

### Structure of Surface Oxide Layer (Heat Treatment Condition)

Depending on the temperature and time of the oxidation heat treatment, a structure that TiO₂ may have exists as anatase, rutile, or a mixture of the two. In terms of corrosion resistance, the relative tendency of these structures is that the rutile structure is more inert than the anatase structure, resulting in superior corrosion resistance, and the TiO₂ oxide layer in the temperature range of 500 to 650° C. is reported to have increased protection performance against corrosion with increasing heat treatment time. In addition, the structure of TiO₂ produced from pure Ti with increasing oxidation heat treatment temperature gradually changes from anatase>anatase+rutile>rutile, which may have higher corrosion resistance. However, in the previously disclosed patented process, the method for forming the conductive oxide layer is performed through the chemical reaction of Ti and O under a limited partial pressure of oxygen, so the temperature and time conditions for heat treatment are very limited. That is, the conductivity is rapidly degraded by TiO₂ growth in conditions beyond this range, which has limitations in securing additional corrosion resistance through the oxidation heat treatment. However, in the present disclosure, since the conductive oxide layer is formed by structural rearrangement through the diffusion of Ti and O atoms rather than by the chemical reaction between Ti—O as in the conventional method, heat treatment may be performed in a relatively wide temperature and time range even in the atmosphere. In other words, the method of securing conductivity through the present developed method enables heat treatment at a higher temperature and for a longer time, which can maximize the rutile fraction of the outer Ti oxide layer, thereby further maximizing corrosion resistance. However, here again, the range of heat treatment conditions under which conductivity is achieved is determined within the temperature-time range where the increased resistance due to the TiO₂ oxide layer produced on the outer surface does not degrade the targeted conductivity, as referenced in the table.

Next, the detailed conditions for the PVD process of the Ti separator coating for a fuel cell implemented through the present disclosure are described in Table 3, and the manufacturing conditions and property evaluation results of the examples and comparative examples for the formation of the described conductive oxide layer and verification of corrosion resistance are shown in Table 4. The details of the manufacturing conditions in each case are as follows

### Example 1

The Ti raw material used was BA heat treated Grade1 material rolled to 0.1 t and then heat treated in an Ar atmosphere at 650° C. for approximately 1 to 2 minutes. Then, Ti ion etching was performed at BIAS 180 eV, for 2 minutes, under vacuum degree of approximately 10⁻⁶ torr and temperature of 100±10° C. in the PVD chamber, and left for 24 hours to form a natural oxide film on the surface after the coating was finished. The oxidation heat treatment was carried out in a conventional induction heating heat treatment furnace under atmospheric atmosphere for \textcircled{1} 600° C. for 10 minutes, \textcircled{2} 620° C. for 7 minutes, and \textcircled{3} 690° C. for 5 minutes, and then taken out and air-cooled in the atmosphere.

### Example 2

The raw material and oxidation heat treatment conditions are the same as in Example 1, and in the PVD process, C deposition after Ti ion etching was performed at BIAS 180 eV, for 2 minutes, as in Example 1.

### Example 3

The Ti raw material used was a sample that was vacuum heat treated after rolling 0.1 t of BA heat treated Grade1 material (vacuum degree 10 to 30 Pa, 650 to 700° C., approximately 1 to 2 minutes of heat treatment) and then subjected to the same PVD-Ti ion etching process as in Example 1, followed by oxidation heat treatment in air for \textcircled{1} 650° C. for 5 minutes and \textcircled{2} 690° C. for 5 minutes, respectively.

### Comparative Example 1-\textcircled{1}

The Ti raw material used was BA heat treated Grade1 Ti material rolled to 0.1 t as it is (non-heat treated). The PVD process was performed under the same process conditions as in Example 2, followed by vacuum heat treatment at 600° C. for 10 minutes (vacuum degree 10 to 30 Pa, temperature rise 20° C./min for 30 minutes, maintained at 600° C. for 10 minutes, chamber cooling for 3 hours).

### Comparative Example 1-\textcircled{2}

On the same raw material as in Comparative Examples 1-\textcircled{1}, the PVD process was performed under the same conditions as in Example 1 followed by Ti ion etching (BIAS 180/70, for 2 minutes), followed by TiO2 deposition (BIAS 100 eV, O2 100 cc, for 2 minutes) and C deposition (BIAS 180 eV, for 2 minutes). The heat treatment was the same as in Comparative Examples 1-\textcircled{1} with vacuum heat treatment.

### Comparative Example 2

BA heat treated pure Ti material was subjected to H₂SO₄ pickling and vacuum reduction heat treatment to form TiO₂₋ₓ on the surface. Then, the C coating was performed after plasma pretreatment in the CVD process. In this case, TiO(C,N) bonding was induced by injecting N₂ in addition to C₂H₂ as a method of attaching C to the surface of the Ti oxide layer. (Temperature 300° C./Pressure 10 Pa/C₂H₂ gas containing N/Voltage DC 2.0 kV)

### Comparative Example 3

A solution dispersed with C nanocomposite after the plasma pretreatment was applied by a roll coater on the surface of the vacuum heat treated Ti grade1 material. The oxidation heat treatment was then carried out at 600 to 620° C. for 10 to 30 seconds in a low oxygen partial pressure of 10 to 30 Pa atmosphere. The TiC compound present on the surface was then cleaned and re-heat treated under vacuum at 580 to 600° C. for about 1 minute to absorb the TiC into the raw material.

TABLE 3

| | PVD Fixation | | | | | | | |
|---|---|---|---|---|---|---|---|---|
| | Batch type | | | | Roll to Roll type | | | |
| Coating condition | Ti Ion Etching | | PVD-C Coating | | Ti Ion Etching | | PVD-C coating | |
| Time | 2 to 3 | min. | 2 to 3 | min. | 2 | m/min | 2 | m/min |
| Temperature/Vacuum | 100 ± 10° C./ | | 100 ± 10° C./ | | 70 ± 20° C./ | | 70 ± 20° C./ | |
| degree | approx. 10⁻⁶ | | approx. 10⁻⁶ | | approx. 1.5 × 10⁻⁵ | | approx. 1.5 × 10⁻⁵ | |
| | torr | | torr | | torr | | torr | |
| Target Power | 80 | A | 80 | A | 22 kW-20 kW | | 22 kW-20 kW | |
| Injection Gas | Ar 50 sccm | | Ar 50 sccm | | Ar 1300 ± 50 | | Ar 1300 ± 50 | |
| | | | | | sccm | | sccm | |
| Acceleration | 180 | V | 100 | V | 80 ± 20 | V | 80 ± 20 | V |
| Voltage | | | | | | | | |
| Ion Source | — | | — | | 1200 ± 300 | V | 1200 ± 300 | V |
| (Pretreatment) | | | | | | | | |

TABLE 4

| | | | | | Change in contact resistance (mΩ-*cm²) | | | |
|---|---|---|---|---|---|---|---|---|
| | | | | | | After | General | Harsh |
| | Ti raw | | Heat Treatment | | | heat | Corrosion | Corrosion |
| | material | Coating | Condition | | As | treatment | [Appearance] | [Appearance] |
| Example 1 | Ar Heat | Ti Ion | Atmospheric | \textcircled{1}600° | 76 to 81 | 0 to 1 | 4 to 5[∘] | — |
| | Treatment | Etching | atmosphere | C.-10 min. | | | | |
| | | | | \textcircled{2}620° | | 1 to 4 | — | 2 to 4[Δ] |
| | | | | C.-7 min. | | | | |
| | | | | \textcircled{3}690° | | 8 to 12 | — | 8[∘] |
| | | | | C.-5 min. | | | | |
| Example 2 | Ar Heat | Ti ion | | \textcircled{1}600° | | 0 to 1 | 0 to 1[∘] | — |
| | Treatment | etching + | | C.-10 min. | | | | |
| | | C-PVD | | \textcircled{2}620° | | 1 to 4 | — | 0~1[x] |
| | | | | C.-7 min. | | | | |
| | | | | \textcircled{3}690° | | 6 to 7 | — | 6[∘] |
| | | | | C.-5 min. | | | | |
| Example 3 | Vacuum Heat | Ti Ion | | 690° | — | 0 to 1 | — | — |
| | Treatment | Etching | | C.-5 min. | | | | |
| Example 4 | Vacuum Heat | Ti ion | | 690° | — | 0 to 1 | — | — |
| | Treatment | etching + | | C.-5 min. | | | | |
| | | C-PVD | | | | | | |
| Comparative | Non-Heat | \textcircled{1}Ti ion | Vacuum | 690° | 10 | 9 | 11[Δ] | — |
| Example 1 | Treatment | etching + | | C.-10 min. | | | | |
| | | C-PVD | | (vacuum | | | | |
| | | \textcircled{2}Ti ion | | atmosphere) | 11 | 10 | 29[x] | — |
| | | etching + | | | | | | |
| | | C-PVD | | | | | | |
| Comparative | Surface | C-PVD | Vacuum | 300° | 10 | | 11[Δ] | — |
| Example 2 | treatment of | | | C.-10 min. | | | | |
| | conductive | | | or more | | | | |
| | oxide layer | | | | | | | |
| Comparative | Vacuum Heat | C-nano | Low oxygen | 620° | 10 to 13 | | 15[∘] | 40~50[x] |
| Example 3 | Treatment | composite | partial | C.-1 min. | | | | |
| | | | pressure | or less | | | | |

In the corrosion appearance, ∘ is good, Δ is partial corrosion, and x is full corrosion.

Next, the results of durability tests of an embodiment of the present disclosure are described.

The corrosion tests were conducted under conditions that simulate a fuel cell environment, by dividing the potentiostatic corrosion evaluation into general and harsh conditions. The conditions for each evaluation method are shown in Table 5 below. (Evaluation equipment: Potentiostat)

TABLE 5

| | Evaluation Condition | | | | Evaluation Standard | |
|---|---|---|---|---|---|---|
| | Potentiostatic Evaluation | | | | | |
| | Corrosion | Applied | Temperature/ | Evaluation | Contact | Corrosion |
| Evaluation Method | Solution | Potential | Time | Area | Resistance | Appearance |
| General | 0.1N H₂SO₄ + | 0.75 V(SEC) | 60° C./72 hr | 6 cm2 | Change in | Degree of |
| Corrosion | 2 ppm HF | | | | resistance | surface |
| Harsh | 0.1N H₂SO₄ + | 0.85 V(SEC) | | (circle) | after | corrosion |
| corrosion | 2 ppm HF + | | | | evaluation | after |
| | 3,000 ppm | | | | | evaluation |
| | H₂O₂ | | | | | (corrosion |
| | | | | | | products) |

Contact resistance measurements for each example and comparative example were performed by inserting an evaluation sample between the gas diffusion layer (GDL) and measuring the voltage applied to the sample by a current under a pressure of 1.0 MPa to calculate the contact resistance. In this way, the contact resistance was compared before and after the corrosion evaluation.

The result of the formation of the conductive oxide layer is described.

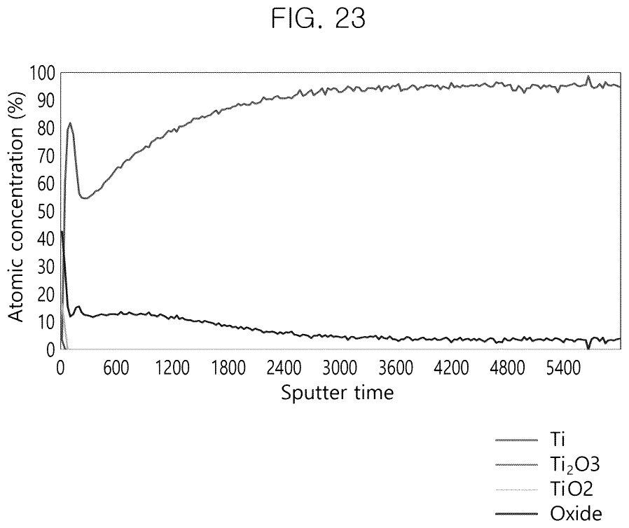

In order to more clearly distinguish the mechanism and position of conductive oxide layer formation by Ar⁺ ion sputtering and Ti ion deposition, Ti ion etching was performed on Ti raw material in the vacuum heat treatment state with a very sparse initial surface oxide layer, as in Example 3 (the thickness of the surface oxide layer in the vacuum heat treatment state is within approximately 10 nm. FIG. 9). The changes in contact resistance by heat treatment temperature and time conditions for the Ti ion etching sample with raw material were then measured and shown in Table 6. TEM, X-ray photoelectron spectroscope (XPS), and RAMAN analysis for each case of a), b), c), and d) were performed to observe changes in the composition and structure of the Ti oxide layer depending on the heat treatment conditions. (FIG. 23 to FIG. 28)

As described above, the reason for using the raw material with little initial surface oxide layer to examine the tendency of Ti oxide formation is to confirm the mechanism of conductive oxide layer formation by Ti ion etching while excluding the oxide layer present on the initial raw material surface as much as possible. That is, by performing Ar⁺ ion etching and Ti ion deposition simultaneously, the phenomenon of the formation of the conductive oxide layer through diffusion rearrangement between the overdeposited Ti elements in the atomic intermixing region near the surface of the raw material and the defects and O particles was attempted to be examined more clearly.

As can be seen from the results in Table 6, when the heat treatment temperature and time required for the diffusion rearrangement of elements and defects in the formation of the conductive oxide layer are insufficient, the contact resistance increases after heat treatment, which is considered to be due to the initial Ti oxide layer formed in the outermost layer. However, after the Ti ion etching, when the heat treatment is carried out for more than 670° C. for 5 minutes or 690° C. for 3 minutes, the contact resistance decreases rapidly and reaches the level of 0 to 1, which is a significantly different trend compared to the results of heat treatment of the raw material without the Ti ion etching under the same conditions.

TABLE 6

| Ti raw material | Coating | Contact resistance by heat treatment condition (mΩ-cm²) | | | | |
|---|---|---|---|---|---|---|
| (contact resistance) | (contact resistance) | Temperature | | 650° C. | 670° C. | 690° C. |
| Vacuum | a) Ti ion | Time | 3 min. | ~1000 | 1300 to 1400 | 0 to 1 |
| heat | etching | | 5 min. | b) 1600 | 0 to 1 | c) 0 to 1 |
| treating | (64) | | | to 1850 | | |
| (18 to 20) | — | | 3 min. | Greater | Greater | d) 1800 |
| | | | | than 1000 | than 1000 | |

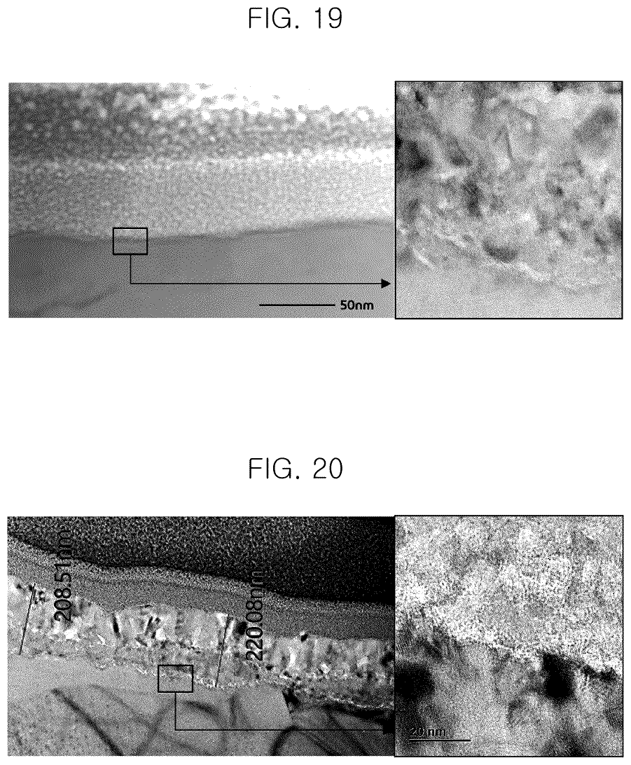

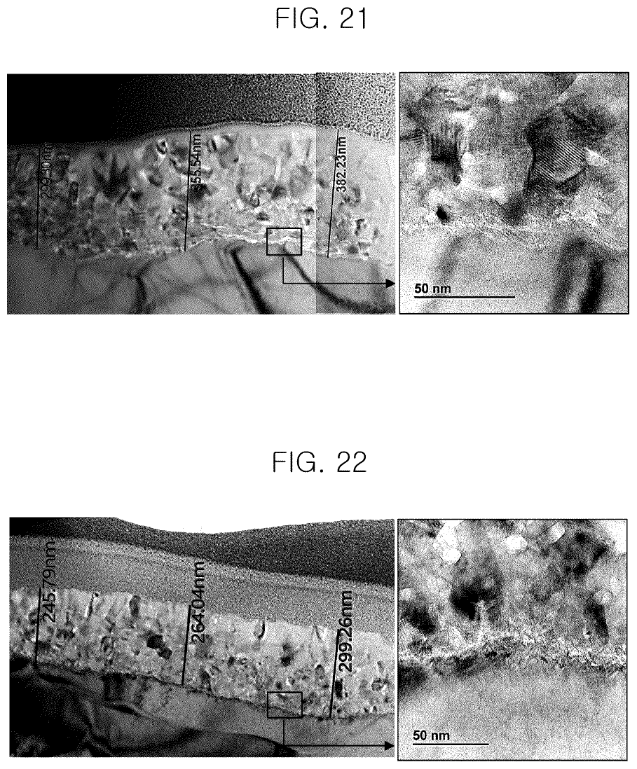

FIGS. 19 to 22 illustrate TEM cross-sectional photographs for each of the materials and heat treatment conditions in Table 6. The vacuum heat treated Ti raw material had a very thin thickness of the oxide layer, less than 10 nm, but after the heat treatment at 690° C. for 3 minutes (FIG. 22), it can be seen that an oxide layer around approximately 300 nm has grown. The appearance of the oxide layer is composed of an inner porous layer and an outer coarse-grained crystalline oxide layer, and the boundary between the oxide layer and the raw material formed by heat treatment is clearly divided. When Ti ion etching is performed on the surface of the vacuum heat treated raw material, the Ti ion deposited layer of approximately 20 to 100 nm (average 50 nm) is formed (FIG. 19). However, since the deposition time was limited to 2 minutes to further facilitate the formation of the conductive oxide layer, the shape of the layer (covering <80%) has a shape of relatively regular bends or irregularities. In particular, it can be seen that the region in contact with the raw material is an atomic intermix layer formed by Ar and Ti ion bombardment, and the boundary with the raw material is almost indistinguishable. FIGS. 20 and 21 are cross-sectional photographs of the oxide layer subjected to the oxidation heat treatment of 650° C. for 5 minutes (1800 mΩ) and 690° C. for 5 minutes (0-1 mΩ), respectively, in this state. First, examining the cross-section of the oxide layer subjected to heat treatment at 650° C. for 5 minutes in FIG. 22, there are a Ti ion deposited layer on the raw material and an oxide layer formed thereon by heat treatment, and the outer oxide layer almost completely covers the Ti ion deposited layer. It can also be seen that the Ti ion deposited layer maintains almost the same thickness and shape as before the heat treatment. That is, it can be seen that this heat treatment temperature-time condition was not yet sufficient to cause diffusion rearrangement between Ti ion particles, defects, and O, and it can be inferred that the contact resistance increased significantly due to the growth of the outer TiO₂ oxide layer. However, in the cross-section of the oxide layer in the state of heat treatment of 690° C. for 5 minutes in FIG. 21, it is observed that the thicknesses of the outer oxide layer and the Ti ion deposited layer grow and expand simultaneously, and the boundary between the Ti ion deposited layer and the oxide layer that was formed on the outer side disappears due to diffusion. That is, it is considered that under the corresponding heat treatment conditions, the conductive oxide layer is formed through the process of diffusion rearrangement between the oxide layer formed on the outer side, the overdeposited Ti particles, the surrounding defects, and O particles to form Ti₁₊ₓO₂.

Examining the boundary region between the Ti raw material and the oxide layer, it can be seen that a crystallized oxide layer with a porous shape has grown on the surface of the raw material when the Ti raw material is heat treated at 690° C. for 3 minutes (enlarged photograph in FIG. 22). It can be seen that the Ti ion deposited layer heat-treated at 650° C. for 5 minutes (enlarged photograph in FIG. 20) after Ti ion etching has blurred grain boundaries, almost maintaining the amorphous phase of Ti ion deposited state (enlarged photograph in FIG. 19) before heat treatment. However, after heat treatment of 690° C. for 5 minutes (enlarged photograph in FIG. 21), a dense, oriented grain structure is observed, unlike the oxide layer formed on the Ti raw material. This is assumed to be due to crystallization by diffusion rearrangement of Ti, O particles and defects at the boundary between the raw material and Ti ion deposition, which is the atomic intermix region, after Ti ion etching and heat treatment under certain time and temperature conditions, resulting in the formation of the conductive oxide layer. In addition, it can be seen that the boundary between the conductive oxide layer and the raw material formed by Ti ion deposition maintains continuity without any obvious distinction, so that the conductive oxide layer implemented through the present disclosure can have an excellent bonding force with the raw material and corrosion resistance. For the above phenomenon, XPS depth profile and Raman spectra were performed to analyze the composition of Ti oxides constituting the oxide layer according to the depth and structural changes by heat treatment conditions, and the results thereof are shown in FIGS. 23 to 26 and FIGS. 27 and 28, respectively.

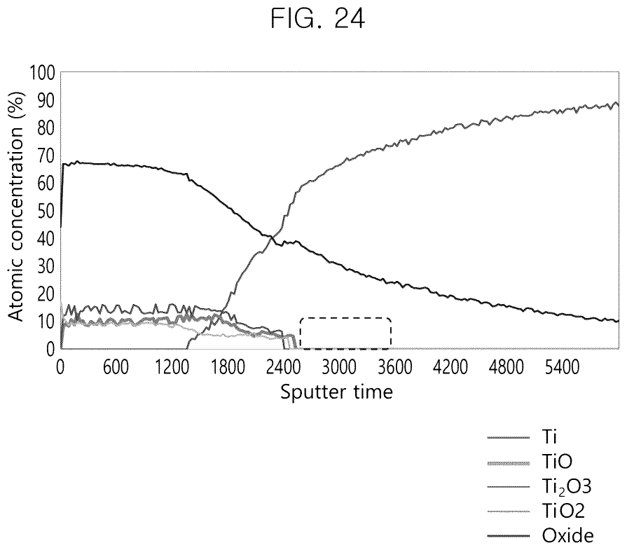

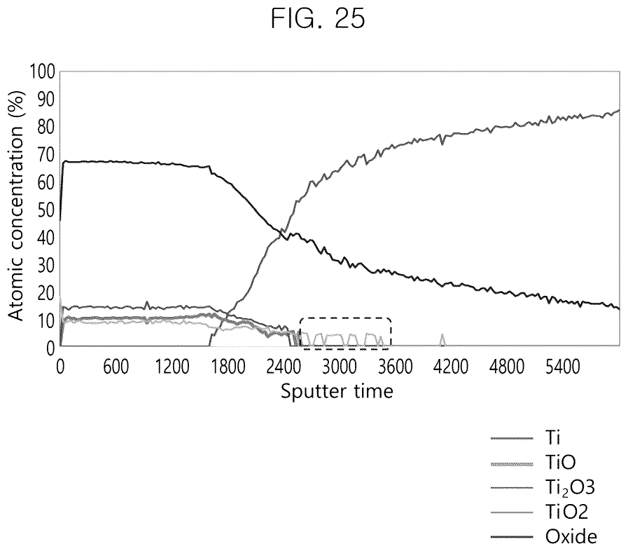

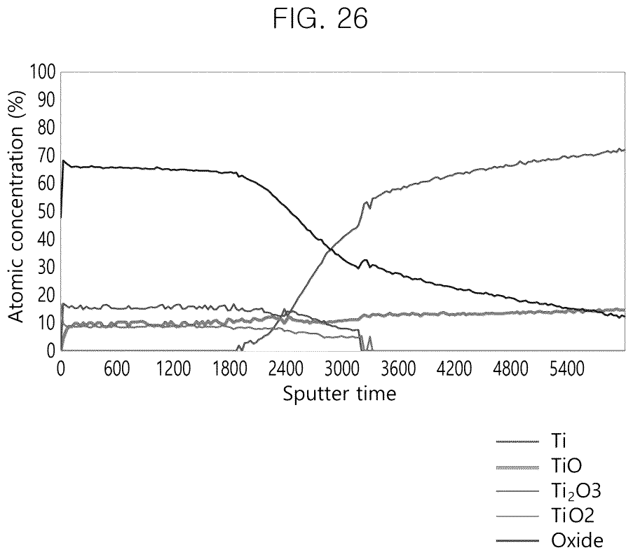

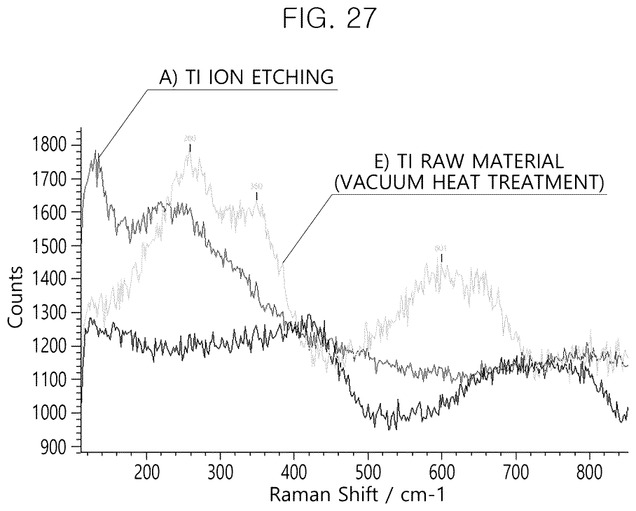

As a result of XPS analysis, it can be seen that when the Ti ion etching is performed on the surface of the raw material, the Ti oxide layer is only partially present and the fraction of Ti on the surface increases (FIG. 23). It can be seen that Ti₂O₃ and TiO oxides in addition to TiO₂ are formed on the outer side of the oxide layer as a result of heat treatment at 650° C. for 5 minutes (FIG. 24), which is similar to the result of oxidation heat treatment of the raw material (FIG. 26). However, when the Ti ion etching is performed as in FIGS. 24 and 25, the fraction of TiO in the oxide layer after heat treatment tends to be maintained slightly higher than that of the raw material (FIG. 26), which seems to be due to the increase of Ti fraction by the Ti ion deposition. In addition, in case of condition b), unlike d), the distribution graph of Ti oxides up to a certain depth is not linear and appears as a serration shape, and the reason for this is considered to be due to localized differences in Ti content for each site by the Ti ion deposition. A distinct difference observed in the XPS results under heat treatment condition c), where the contact resistance decreases rapidly, unlike conditions d) or b) of the raw material, is that when sufficient heat treatment is performed after the Ti ion etching, a new TiO₂ fraction, that is, a component assumed to be TiO₂₋ₓ, is formed to a certain depth in a direction from the inside of the oxide layer to the bulk of the raw material, as illustrated in FIG. 27. This is a phenomenon that is not observed in the XPS results (FIG. 26) under the same heat treatment condition (d) of the Ti raw material or in the XPS results (FIG. 24) under a lower temperature condition (b) after the Ti ion etching. That is, it can be inferred that the difference in contact resistance is caused by whether the TiO₂₋ₓ layer is formed on the inside of the oxide layer. It is considered that the conductive oxide layer is formed underneath the surface of the raw material through the heat treatment process after the Ti ion etching. This is inferred that the defects formed by the Ar⁺ ion bombardment with the Ti particles overdeposited by the Ti ion etching are formed by the diffusion rearrangement process inside the raw material with O rather than the chemical reaction of O and Ti in the atmosphere on the surface of the raw material. The reason that the TiO₂ oxide distribution graph in this region also shows a serration shape as illustrated in FIG. 24 is that the distribution and depth of the disorder and atomic intermix region formed inside the raw material during the Ti ion etching cannot be locally uniform, so the distribution tendency of the Ti₁₊ₓO₂ conductive oxide layer formed after the heat treatment also follows this tendency.

FIGS. 27 and 29 illustrate the RAMAN analysis results to examine the changes in the composition of the oxide layer in response to the Ti ion etching.

The oxide layer in the initial vacuum heat treated state is very sparse, making it difficult to obtain Raman analysis information on the Ti oxide due to the Ti of the raw material, but roughly rutile peaks are visible, and it can be seen that the surface oxide layer exposed to the atmosphere at room temperature after the Ti ion etching exists in an amorphous state with some anatase, as seen in the broad peaks in FIG. 27 at A). However, it can be seen that after heat treatment according to the conditions in Table 6, the structure is changed to a structure with some anatase based on rutile in common, although with slight differences in each case (the main peaks of rutile Ti oxide appear at 240, 443, and 610, and others at 319, 707, and 818). However, examining the changes of the main peaks in the Raman spectrum with temperature and time of heat treatment in relation to the phenomenon of rapidly decreasing resistance, it can be seen that the peaks of condition c) 690° C. for 5 minutes compared to condition b) 650° C. for 5 minutes have more distinct intensity and the positions of the main peaks that were shifted return to original positions (rutile 240 and 443), and new peaks such as 172 and 319 appear in positions that were not present before.

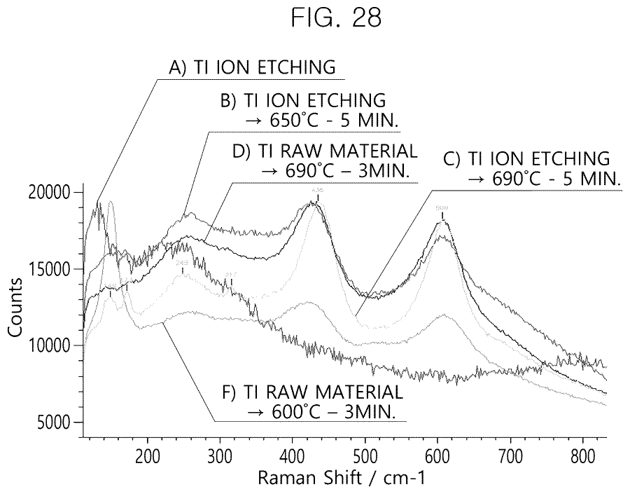

In a conventional reducing atmosphere, the formation of TiO₂₋ₓ was shown to be a phenomenon in which the main rutile peaks in the Raman spectra broadened or shifted away from the original positions as the TiO2 oxide layer changed from a stoichiometric to a non-stoichiometric structure due to O deficiency, that is, the introduction of O vacancies in the lattice. However, in the present development, it was shown that the initial Ti deposition and the disorder state caused by ion bombardment appeared as broad peaks in the Raman spectra, but after heat treatment, the shape of the peaks became distinct as the crystal structure gradually recovered through the diffusion rearrangement process in addition to the formation of TiO₂, and the shifted peaks returned to the original positions. However, in condition c), where the contact resistance decreased rapidly, it can be seen that an intermediate peak, 173, which belongs to neither anatase nor rutile, and a minor peak, 319 of rutile, appear (FIG. 28 at C)). This is considered to be the peaks originated from a newly formed conductive oxide layer by diffusion rearrangement inside the oxide layer. Considering that the peaks do not appear in the Ti raw material heat treated at the same temperature and for a similar time (FIG. 28 at D)) and in the condition heat treated at a lower temperature and for the same time after the Ti ion etching (FIG. 28 at B)), the appearance of these peaks in condition c) is believed to be an evidence of the formation of the conductive oxide layer by the Ti ion etching, and the correlation is also confirmed by the results of the conditions in FIG. 25 on XPS.

Next, the results of the corrosion resistance evaluation are described.

To verify the corrosion resistance of the coating of the present disclosure, the potentiostatic corrosion evaluation was performed on each of Examples 1 and 2 and Comparative Examples 1, 2, and 3, and then the corrosion appearance and changes in contact resistance after the evaluation were measured. The potentiostatic corrosion evaluation was divided into 1) a general corrosion evaluation corresponding to a general fuel cell operating potential and environment, and 2) a harsh corrosion evaluation to verify higher durability than that of the general corrosion evaluation, and the results thereof are shown in Table 7.

TABLE 7

| | 1) General corrosion | | | | | | 2) Harsh corrosion | | |
|---|---|---|---|---|---|---|---|---|---|
| | (0.75 V-H₂SO₄) | | | | | | (0.85 V-H₂SO₄ + H₂O₂) | | |
| | Evaluation sample | | | | | | | | |
| | | | 1) Compar- | Compar- | Compar- | Compar- | | | Compar- |
| | | | ative | ative | ative | ative | | | ative |
| Evaluation Method | Example 1-1 | Example 1-1 | Example 1 | Example 1-2 | Example 2 | Example 3 | Example 1-2 | Example 2-2 | Example 3 |
| Corrosion | ◯ | ◯ | Δ | X | Δ | ◯ | Δ | X | X |
| appearance | | | | | | | | | |
| (◯: Good | | | | | | | | | |
| Δ: Partial | | | | | | | | | |
| corrosion | | | | | | | | | |
| X: Full | | | | | | | | | |
| corrosion) | | | | | | | | | |
| Contact | 0 to | 0 to | 9→77 | 10→29 | 10→11 | 13→15 | 4→3 to 4 | 0 to | 10→40 |
| Resistance | 1→4 to 5 | 1→0 to 1 | | | | | | 1→0 to 1 | to 50 |
| (Before→After | | | | | | | | | |
| Evaluation) | | | | | | | | | |

1) As a result of the general corrosion evaluation, the change in contact resistance before and after the evaluation was favorable for all examples and comparative examples, except for Comparative Examples 1-2, with no significant increase. However, when comparing the corrosion appearance, it can be seen that for Examples 1-1 and 2-1 and Comparative Example 3, no damage due to the surface corrosion was observed, but for the remaining comparative examples, the coating layer on the surface was partially corroded and delaminated. This is a result showing that while both examples and comparative examples use the Ti oxide layer of the raw material to achieve conductivity, the corrosion resistance may vary depending on the way of being implemented. Among these, it can be seen that Comparative Examples 1-2 show the worst corrosion resistance, not only because of delamination due to corrosion, but also because of increased contact resistance after evaluation. Comparative Examples 1-2 is a case where the TiO₂ oxide layer was reduced and the conductive oxide layer was formed by vacuum heat treatment after C deposition on the surface of the TiO₂ oxide layer, but the result thereof was even worse than that of Comparative Examples 1-1, where C deposition was performed after Ti ion etching. It can be seen from these results that when the conductive oxide layer exists in the outermost position and is directly exposed to the corrosive environment, the corrosion resistance may be even worse. In addition, possible Ti carbide formation during the C application and heat treatment process (coating layer delamination due to TiC corrosion) may have contributed to another cause of corrosion resistance degradation.

According to the existing patents, in case of Comparative Examples 1 and 2, the corrosion resistance is determined by the oxide layer formed by the reduction heat treatment condition, but it is limited to secure further corrosion resistance due to the phenomenon of conductivity degradation by increasing the thickness of the oxide layer under conditions above a specific temperature and time. In contrast, the reason that the corrosion resistance of Examples 1-1 and 2-1 and Comparative Example 3 was superior to that of Examples 1-1 and 1-2 and Comparative Example 2 in the general corrosion evaluation condition may be considered to be due to the higher temperature of that in the heat treatment condition in which the Ti oxide layer was formed. In case of Comparative Examples 1-1 and 2, the vacuum heat treatment after C coating does not contribute to the formation of the Ti oxide layer required for corrosion resistance, and in case of Comparative Example 2, the heat treatment temperature for the formation of the conductive oxide layer before C coating is rather low, around 300° C. However, it can be seen that the Ti oxide layer formed around 600° C. as in Examples 1 and 2 and Comparative Example 3 exhibits more superior corrosion resistance.

Severe corrosion evaluation was performed on Examples 1-1 and 2-1 and Comparative Example 3, which were confirmed to have better corrosion resistance. However, in this section, the results of Examples 1-2 and 2-2 with slightly changed heat treatment conditions are shown, although there is little difference in the evaluation results. As a result, it can be seen that the appearance of the evaluation sites were all damaged or partially delaminated by corrosion. However, as a result of comparing the contact resistance before and after the evaluation, the contact resistance of Examples 1-2 and 2-2 remained the same as the initial state, while that of Example 3 increased significantly. In Comparative Example 3, the reason for the increase in resistance simultaneous with the delamination of the coating layer by surface corrosion is that the conductive oxide layer that was formed on the surface of the Ti raw material under the harsh corrosion evaluation conditions was removed by corrosion. In contrast, in case of Examples 1-2 and 2-2, the reason that the contact resistance remains unchanged even though the outer oxide layer is removed beyond a certain level due to the progress of surface corrosion may be considered that the position of the conductive oxide layer does not exist at the outer side of the oxide layer, but is distributed inside the oxide layer and at or below the boundary with the surface of the raw material (in bulk), so that the conductivity is maintained even if the outer oxide layer is partially corroded. This is considered to be a factor that makes the coating method of the present development more durable due to the position and shape of the formation of the conductive oxide layer, as previously described for the mechanism in which the conductive oxide layer is formed through the Ti ion etching and heat treatment method.

Table 8 shows the results of harsh corrosion evaluation as a function of temperature and time to verify oxidation heat treatment conditions that may further enhance corrosion resistance for Examples 1 and 2.

TABLE 8

| Evaluation sample | | Example 1. Ti Ion Etching | | | | Example 2. Ti ion etching + C | | | |
|---|---|---|---|---|---|---|---|---|---|
| Oxidation | Temperature | 620 | 650 | 690 | 690 | 620 | 650 | 690 | 690 |
| heat treatment | Time | 7 | 5 | 2.2(3) | 5 | 7 | 5 | 1.5 | 5 |

| | | | | | | | | |
|---|---|---|---|---|---|---|---|---|
| Degree of corrosion | x to Δ | Δ | Δ | ∘ | x | x to Δ | x | ∘ |
| appearance | | | | | | | | |
| Corrosion-producing | Medium | Medium | Medium | Small | Large | Large | Large | Small |
| oxides (tape | to large | | | | | | | |
| delamination) | | | | | | | | |
| Contact Resistance | 4→2 | 8→8 | 1 to | 10 to | 0 to | 0 to | 0 to | 6 to |
| Before→After | to 3 | | 5→3 to 5 | 12→8 to 9 | 1→0 to 1 | 1→0 to 1 | 1→0 to 1 | 7→6 to 7 |
| Evaluation) | | | | | | | | |

※ Degree of corrosion appearance - ∘: good, Δ: partial corrosion, x: full corrosion)

As a result of the harsh corrosion evaluation for each condition, there was no increase in contact resistance after the evaluation for both Examples 1 and 2, but the phenomenon of oxide layer delamination due to surface corrosion was more noticeable in Examples 2 with C deposition compared to Examples 1. In case of Example 1, the surface oxide layer corrosion decreased as the temperature and time increased, and it was confirmed that the oxide layer delamination did not almost occur when the heat treatment was performed at 690° C. for 5 minutes as in Examples 1-3. In Example 2, the oxide layer corrosion occurred very clearly at a temperature of 690° C. or less regardless of the heat treatment condition, but the phenomenon of oxide layer delamination tended to decrease significantly when the heat treatment was performed at 690° C. for 5 minutes as in Examples 2-3. This is considered to be due to the fact that the structure of the outer Ti oxide layer approaches a more rutile structure at 690° C. for 5 minutes or more, which increases the corrosion resistance, just as the structure of the Ti oxide layer changes from anatase (active) to rutile (inert) as the heat treatment time increases at a temperature of 500 to 650° C., which increases the corrosion resistance. These results can also be seen in the Raman analysis results in FIGS. 27 and 28. In case of FIG. 28 at F), where the Ti raw material was heat treated at 600° C. for 3 minutes, the surface oxide layer is mainly anatase structure and contains some rutile, but in case of FIG. 28 at D), where the Ti raw material was heat treated at 690° C. for 3 minutes, it can be seen that the surface oxide layer changes to almost rutile structure. It can be seen that the rutile peak appears more clearly at higher temperatures, while the position of the peak also shifts towards the original rutile peak value, even if comparing the samples heat-treated at 650° C. for 5 minutes (FIG. 28 at B)) and 690° C. for 5 minutes (FIG. 28 at C)) after Ti ion etching, respectively. As such, in the present disclosure, it is possible to increase corrosion resistance while maintaining conductivity by controlling temperature and time through oxidation heat treatment in the atmosphere as in Examples 1 and 2, because the principle of forming the conductive oxide layer is different from the conventional methods. The conventional methods require the oxide layer, which is responsible for conductivity and corrosion resistance, to be in one region at the same time. Therefore, when the structure of the oxide layer was changed to meet the increased corrosion resistance, the conductivity was degraded, which put a limitation on setting the heat treatment conditions. For example, in case of Comparative Example 2, the conductivity of the oxide layer can be secured only by conducting the oxidation heat treatment at 600° C. within 1 minute at low oxygen partial pressure, but further increase of corrosion resistance by heat treatment is difficult because the structure is mainly composed of anatase phase, which becomes less conductive when deviating from the presented heat treatment temperature and time conditions. However, the present disclosure is relatively less constrained by the external atmospheric environment and temperature because the conductive oxide layer is, according to the method, not only positioned inside the entire oxide layer and near the surface of the raw material, but is also formed through diffusion rearrangement inside the material rather than through an oxidation-reduction reaction between Ti and O under the external atmospheric environment. That is, during the heat treatment, the inner conductive oxide layer is formed separately from the oxide layer formed on the outer side. Therefore, it is possible to change the structure of the outer oxide layer, which can serve as a protective layer, to a structure that is more resistant to a corrosive environment by controlling the heat treatment temperature and time.

Meanwhile, the present disclosure includes the following modified examples.

### Modified Example 1

In addition to a Ti target, a TiSi based alloy target containing Si (2 to 30%) may also be used to secure the targeted contact resistance and corrosion resistance.

For example, a case in which TiSi ion etching is performed, TiSiO₂ deposition coating or TiSiO₂ deposition coating+C deposition coating, followed by heat treatment is included, and the results thereof are shown in Table 9 below.

TABLE 9

| PVD | Heat treatment | | | Contact resistance (mΩ-cm²) | | |
|---|---|---|---|---|---|---|
| TiSi target | Temperature | | | 600° C. | 650° C. | 690° C. |
| (contact | | | | | | |
| resistance) | | | | | | |
| TiSi ion | Time | 3 | min. | — | 6 to 7 | 5.5 to 6.4 |
| etching (47) | | 5 | min. | 11 to 12 | 6.7 to 7.7 | 5.7 |
| | | 10 | min. | 10 to 12 | — | — |
| TiSiO₂ | | 3 | min. | — | 4.6 | 0.6 to 2.8 |
| deposition(81) | | 5 | min. | 2 to 3 | 4.2 | 4.2 to 5.3 |
| | | 10 | min. | 4 to 5.1 | — | — |

### Modified Example 2

In addition to Ti ion etching, when performing [Ti ion etching TiO2 deposition coating], it is possible to achieve the targeted contact resistance and a certain level of corrosion resistance under some heat treatment conditions, and the results thereof are shown in Table 10 below.

### Modified Example PVD Process Condition

Ti or TiSi ion etch condition: Acceleration voltage 180 eV for 2 minutes
TiO₂ or TiSiO₂ deposition condition: Acceleration voltage 100 eV, O2 gas 100 sccm, for 2 minutes
C deposition condition: Acceleration voltage 100 eV, for 2 minutes

TABLE 10

| Coating | TiSiO₂ + C coating | Ti ion/TiO₂ + C coating |
|---|---|---|
| Heat treatment | 610° C. 10 min. | 610° C. 10 min. |
| Before evaluation (Ω) | 1 to 2 | 0 to 1 |
| After potentiostatic | 3 to 5 | 2 to 3 |
| corrosion evaluation (Ω) | | |

While the present disclosure has been described with reference to the exemplified drawings, it is obvious to those skilled in the art that the present disclosure is not limited to the aforementioned embodiments, and may be variously changed and modified without departing from the spirit and the scope of the present disclosure. Accordingly, the changed or modified examples belong to the claims of the present disclosure and the scope of the present disclosure should be interpreted on the basis of the appended claims.

1. A method of manufacturing a Ti material for a fuel cell separator, the method comprising:
rolling a Ti raw material of a pure Ti material or a Ti alloy material;
deposition coating Ti ion particles on the Ti raw material by physical vapor deposition (PVD); and
oxidation heat treating to form a conductive oxide layer of a TiO₂₋ₓ(0<x<1) structure around the Ti ion particles deposited by the deposition coating.

2. The method of claim 1, wherein Ar⁺ ions from the deposition coating etch a portion of a surface oxide layer of the Ti raw material and are ion bombarded on a surface of the Ti raw material.

3. The method of claim 2, wherein, by the deposition coating, a Ti ion deposited layer is formed on the surface oxide layer, on the etched surface of the Ti raw material and inside underneath the surface oxide layer of the Ti raw material, and an atomic intermix region is formed in which the Ti of the raw material and the deposited Ti ion particles are mixed.

4. The method of claim 3, wherein the oxidation heat treating is carried out in an atmospheric state, and
wherein Ti elements of the surface oxide layer and the Ti ion particles are reacted with oxygen by the oxidation heat treating to form an atmospheric heat treated oxide layer.

5. The method of claim 3, wherein in the oxidation heat treating, the conductive oxide layer of the structure TiO₂₋ₓ(0<x<1) is formed through diffusion rearrangement between Ti particles overdeposited within the Ti ion deposited layer, defects, and O particles introduced from the atmosphere or present within the surface oxide layer.

6. The method of claim 3, further comprising:
coating C particles on the surface oxide layer and the Ti ion deposited layer after the deposition coating,
wherein the C particles are diffused inside the surface oxide layer and the Ti ion deposited layer by the oxidation heat treating.

7. The method of claim 3, wherein an acceleration voltage of the deposition coating is 80 to 800 eV.

8. The method of claim 7, wherein an area fraction (covering %) on the surface of the Ti raw material of the Ti ion deposited layer is 50 to 90%.

9. The method of claim 3, wherein a thickness of the conductive oxide layer is 50 to 500 nm.

10. The method of claim 3, wherein a heat treatment temperature of the oxidation heat treating is 580 to 750° C., and a holding time is 1 to 10 minutes.

11. A Ti material for a fuel cell separator, the Ti material comprising:
a Ti raw material made of a pure Ti material or a Ti alloy material;
a surface oxide layer formed on the Ti raw material;
a Ti ion deposited layer in which Ti ion particles are deposited and coated by physical vapor deposition (PVD) on the Ti raw material and on the surface oxide layer; and
a conductive oxide layer formed in a TiO₂₋ₓ(0<x<1) structure around the deposited Ti ion particles.

12. The Ti material of claim 11, wherein the Ti ion deposited layer is formed on the Ti raw material in which a portion of the surface oxide layer is etched and exposed by Ar⁺ ions by the PVD.

13. The Ti material of claim 12, wherein the Ti ion deposited layer is formed on the surface oxide layer, on the etched surface of the Ti raw material and inside underneath the surface oxide layer of the Ti raw material, and an atomic intermix region is formed in which the Ti of the raw material and the deposited Ti ion particles are mixed.

14. The Ti material of claim 13, further comprising:
an atmospheric heat treated oxide layer formed on the surface oxide layer and on a surface of the etched Ti raw material by reacting Ti elements of the surface oxide layer and the Ti ion particles with oxygen by the oxidation heat treating.

15. The Ti material of claim 13, wherein, by an oxidation heat treatment, the conductive oxide layer of the structure TiO₂₋ₓ(0<x<1) is formed through diffusion rearrangement between Ti particles overdeposited within the Ti ion deposited layer, defects, and O particles introduced from the atmosphere or present within the surface oxide layer.

16. The Ti material of claim 13, further comprising:
C particles coated on the surface oxide layer and on the Ti ion deposited layer and then diffused inside the surface oxide layer and the Ti ion deposited layer by an oxidation heat treatment.

17. The Ti material of claim 13, wherein the Ti raw material is Ar heat treated or vacuum heat treated.

18. The Ti material of claim 13, wherein an area fraction (covering %) on the surface of the Ti raw material of the Ti ion deposited layer is 50 to 90%.

19. The Ti material of claim 13, wherein a thickness of the conductive oxide layer is 50 to 500 nm.
